(19) United States
(12) Patent Application Publication
(10) Pub. No.: US 2025/0110175 A1
(43) Pub. Date: Apr. 3, 2025

(54) METHOD AND APPARATUS TO DETECT COMPUTING SYSTEM HARDWARE DEFECTS USING A PORTABLE STORAGE DEVICE

(71) Applicant: Intel Corporation, Santa Clara, CA (US)

(72) Inventors: Rakesh KANDULA, Bangalore (IN); Sankaran M. MENON, Austin, TX (US); Rolf KUEHNIS, Portland, OR (US)

(21) Appl. No.: 18/374,198

(22) Filed: Sep. 28, 2023

(51) Int. Cl. G01R 31/319; G01R 31/28; G01R 31/317; G01R 31/3185

(52) U.S. Cl. CPC G01R 31/31917; G01R 31/2812; G01R 31/31719; G01R 31/318561

(57) ABSTRACT

Methods, apparatus, and computer programs are disclosed to detect computing system hardware defects using a portable storage device. In one embodiment, a method includes accessing a portable storage device to obtain an identifier and a set of test patterns to test a set of circuits of a computing system, the identifier to map to the set of test patterns. The method further includes determining that the set of test patterns is to be executed on the computing system based on the identifier to be obtained from accessing the portable storage device. Responsive to the determination, and executing the set of test patterns loaded from the portable storage device on the set of circuits of the computing system to detect one or more hardware defects of the set of circuits.

### TECHNICAL FIELD

Embodiments of the disclosure relate to the field of computing; and more specifically, the embodiments are related to detecting computing system hardware defects using a portable storage device.

### BACKGROUND ART

For semiconductor manufacturers, product returns cause significant expenses. Product returns to a semiconductor manufacturer are classified into different types (often referred to as product return types, PRT), including customer returns by end users, vendor returns by system vendors, and manufacturing returns by the factory. A semiconductor manufacturer prefers to reduce product returns (PRT reduction) by running in-field tests to triage hardware defects, so that only defective products due to issues of the semiconductor manufacturer are shipped back to the manufacturer, while other defective products are to be handled locally.

Currently a computer semiconductor manufacturer typically uses a large, specialized piece of equipment to run the in-field manufacturing tests on a computer processor/device for the triage. Such equipment is often referred to as a big-iron tester, and it is cumbersome and expensive to bring the big-iron tester out of the manufacturer's site to run the manufacturing tests in-field at locations where the products are designed, manufactured, and/or deployed. It is preferrable to perform such manufacturing tests and/or corresponding root-cause analysis (collectively referred to as in-field tests) without a big-iron tester so that the manufacturing test can be done efficiently and in scale.

### BRIEF DESCRIPTION OF THE DRAWINGS

The disclosure may best be understood by referring to the following description and accompanying drawings that are used to show embodiments of the disclosure.

FIG. 1 illustrates a system to detect hardware defects using a portable storage device per some embodiments.

FIG. 2 illustrates a system to detect hardware defects using a USB device per some embodiments.

FIG. 3 illustrates test result collection and storage per some embodiments.

FIG. 4 illustrates a flow diagram to show the operations to detect hardware defects using a portable storage device per some embodiments.

FIG. 5 illustrates high level code segments corresponding to operations to be performed to detect hardware defects using a portable storage device per some embodiments.

FIG. 6 illustrates encryption of test patterns to detect hardware defects per some embodiments.

FIG. 7 illustrates a block group structure and a test sequence structure after encryption per some embodiments.

FIG. 8 illustrates Advanced Encryption Standard (AES) encryption of test patterns for a system to detect hardware defects using a portable storage device per some embodiments.

FIG. 9 illustrates decryption of a byte stream for hardware defect detection using a portable storage device per some embodiments.

FIG. 10 illustrates Advanced Encryption Standard (AES) decryption of encrypted data for a system to detect hardware defects using a portable storage device per some embodiments.

FIG. 11 illustrates block verification of a test sequence per some embodiments.

FIG. 12 illustrates security enhance of an AES nonce per some embodiments.

FIG. 13 illustrates a flow diagram to detect hardware defects using a portable storage device per some embodiments.

FIG. 14 illustrates an example computing system.

FIG. 15 illustrates a block diagram of an example processor and/or System on a Chip (SoC) that may have one or more cores and an integrated memory controller.

FIG. 16 is a block diagram illustrating a computing system 1600 configured to implement one or more aspects of the examples described herein.

FIG. 17A illustrates examples of a parallel processor.

FIG. 17B illustrates examples of a block diagram of a partition unit.

FIG. 17C illustrates examples of a block diagram of a processing cluster within a parallel processing unit.

FIG. 17D illustrates examples of a graphics multiprocessor in which the graphics multiprocessor couples with the pipeline manager of the processing cluster.

FIGS. 18A-18C illustrate additional graphics multiprocessors, according to examples.

FIG. 19A is a block diagram illustrating both an example in-order pipeline and an example register renaming, out-of-order issue/execution pipeline according to examples.

FIG. 19B is a block diagram illustrating both an example in-order architecture core and an example register renaming, out-of-order issue/execution architecture core to be included in a processor according to examples.

FIG. 20 illustrates examples of execution unit(s) circuitry, such as execution unit(s) circuitry.

FIGS. 21A-21B illustrate thread execution logic including an array of processing elements employed in a graphics processor core according to examples described herein.

FIG. 22 is a block diagram of another example of a graphics processor.

### DETAILED DESCRIPTION

In the following description, numerous specific details are set forth. However, it is understood that embodiments of the disclosure may be practiced without these specific details. In other instances, well-known circuits, structures, and techniques have not been shown in detail in order not to obscure the understanding of this description.

Bracketed text and blocks with dashed borders (such as large dashes, small dashes, dot-dash, and dots) may be used to illustrate optional operations that add additional features to the embodiments of the disclosure. Such notation, however, should not be taken to mean that these are the only options or optional operations, and/or that blocks with solid borders are not optional in some embodiments of the disclosure.

References in the specification to “one embodiment,” “an embodiment,” “an example embodiment,” etc. indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The terms “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. A “set,” as used herein, refers to any positive whole number of items including one item.

### Computer Manufacture Product Return Reduction Techniques

In computer processor manufacturing, it is challenging for a semiconductor manufacturer to handle product returns. After supposedly defective products are returned to their computer processor manufacturer, each is to be triaged individually and dealt with based on the identified root cause. The manufacturer may identify the root cause of a product return as a structural defect or aging defect of the product. For example, the structural defect may be due to the layout of the transistors and connections between the transistors in the product (e.g., a System-on-Chip (SoC)), or due to issues of cells (e.g., a cell being a central processing unit (CPU), a graphics processing unit (GPU), or another digital logic system that is predefined and/or pre-characterized) that may manifest in the product because of heavy workloads on the product or aging components within the product. An aging defect is related to the gradual degradation of electronic components over time due to various factors like temperature, voltage stress, and usage patterns. Such product return is proper as the manufacturer needs to correct the structural/aging defect in the related products to improve manufacturing quality.

On the other hand, the semiconductor manufacturer may identify the root cause of a product return to be a logical defect, for which the semiconductor manufacturer is not responsible. For example, the logical defect may be a functional, software, or firmware defect of the product, where incorrect computations incur not due to hardware defects, but due to errors in the design or functionality of the product's logic circuitry. Such defects, e.g., pipeline hazards, data corruption, control flow errors, microarchitectural flows, may be addressed without shipping the product back to the manufacturer, but corrected in-field by parties like a computer vendor or an Original Equipment Manufacturer (OEM) that puts the product into their computer. Thus, the semiconductor manufacturer would return such products back to field without improving the manufacture quality. Handling the product returns due to logical defects can be costly and inefficient to the semiconductor manufacturer.

To address the efficiency issues, the root-cause analysis may be done at the locations where a computer product is designed, manufactured, and/or deployed. After the analysis, only defective products with structural/aging defects are returned to the semiconductor manufacturer at the corresponding locations to process further. Yet doing in-field tests with a big-iron tester is cumbersome and expensive, and alternative solutions are preferrable.

One alternative solution is the opposite of in-field tests, where testing is run remotely from the location where the product is designed, manufactured, and/or deployed. For example, the remote debugging solutions to test a processor, such as the encrypted Debug application (referred to as enDebug), include execution of scan patterns to step through instructions, set breakpoints, and inspect the internal state of the processor.

Yet remote debugging incurs huge delays just to acquire the scan dump data or array dump data. For example, enDebug uses short instructions over a secure channel from the customer Target System (TS) to Debug and Test System (DTS) resulting in considerable latency per instruction. Performing the entire set of high-volume manufacturing (HVM) patterns through remote debugging causes considerable delay in the time to market (TTM) and is thus impractical.

Another alternative is portable solutions such as closed chassis debug (CCD), which uses a Universal Serial Bus (USB) Type C receptacle/connector to perform scan dump and array freeze dump at Original Equipment Manufacturer (OEM) sites and these dumped data may be used in debugging manufacturing issues. The debug data typically extracted by CCD is Scan Dump data or Array freeze dump data. The extracted Scan/Array freeze dump data indicates the state of all the sequential elements/arrays (memories) in the partition and/or SoC under debug at given points of time. The points of time to collect the debug data are decided by trigger architecture blocks such as micro-breakpoint controller or by the trigger engine, enabled based on the hang or debug scenario. Standardization bodies such as the Institute of Electrical and Electronics Engineers (IEEE) have proposed standards such as IEEE P2929 for system-level state extraction for functional validation and debugging.

The existing portable solutions such as CCD have several drawbacks. For example, the trigger provided by users using existing debug hardware trigger logic or software could be very random and is delayed by many thousands to millions of clock cycles away from the time/site of actual functional defect manifested in the SoC under debug. The reason is that the conditions to create trigger to exactly mimic the actual defect manifested in silicon is almost impossible. Note that the terms “bug” and “defect” are used interchangeably herein.

Additionally, while the existing technologies to collect debug data are useful to debug logical defects, they may not root cause the issues related to structural/aging defects. For example, if a SoC at a customer site has an aging defect, the debugging with scan Dump/Array freeze dump may take several days to months, and on occasion, the scan dump/array freeze dump cannot even root cause the issues at all.

The structure/aging defects, however, can be effectively root-caused using structural tests such as Stuck@, @Speed, Array tests, or Cell aware tests. These structural tests also root cause these and other defects significantly faster than the scan dump/array freeze dump utilized in CCD.

Thus, some embodiments offer portable solutions to perform the root-cause analysis at the locations where a computing product is designed/manufactured/deployed with (1) structural tests as well as (2) logical testing through scan dump data/Array freeze dump data by using a portable storage device. Such approach gives a holistic debug capability to root-cause both of (i) structural/aging defects manifested (e.g., to be found through the structural tests) as well as (ii) logical defects (e.g., to be found through scan dump data/Array freeze dump data). Accordingly, the products with logical defects may be kept at the computer vendor or OEM sites (since they would be responsible for such defects), and the ones with structural/aging defects may be shipped back to the semiconductor manufacturer. The triage of defective product types in-field, without the big iron testers, alleviates the burden on the semiconductor manufacturers, because only returning the products with structural defects to the manufacturer reduces product return types (PRTs). Accordingly, these embodiments avoid considerable financial stress on a semiconductor manufacturer and save bandwidth of engineers and costs of transport and operating big-iron testers in-field. Additionally, some embodiments offer portable solutions with encryption to provide tests in-field tests securely.

The test patterns stored in the portable storage device are mapped to one or more identifiers, and such identification indicates the specific target system(s) for which the test patterns are to be executed, and the mapping allows the specific target systems(s) to execute only the test patterns generated for the target system(s). In some embodiments, the test patterns and/or the one or more identifiers are encrypted in the portable storage device, so that only the specific target system(s) that are authorized can decrypt the test patterns and/or the one or more identifiers and use the result of which to troubleshoot. The encryption adds additional security to these embodiments as it prevents unauthorized access by a third party.

One or more portable storage devices are used in the portable solutions. While embodiments are explained using a USB device (also referred to as USB stick, USB flash drive, or thumb drive) as an example of the portable storage device, other portable storage device may also be used in some embodiments, including secure digital (SD) cards, MicroSD cards, network attached storage (NAS) devices, solid-state devices (SSDs), external SSDs (eSSDs), and compact discs (CDs)/digital versatile discs (DVDs). Embodiments herein are not limited to a particular portable storage device type.

Architecture to Test using Portable Storage Device

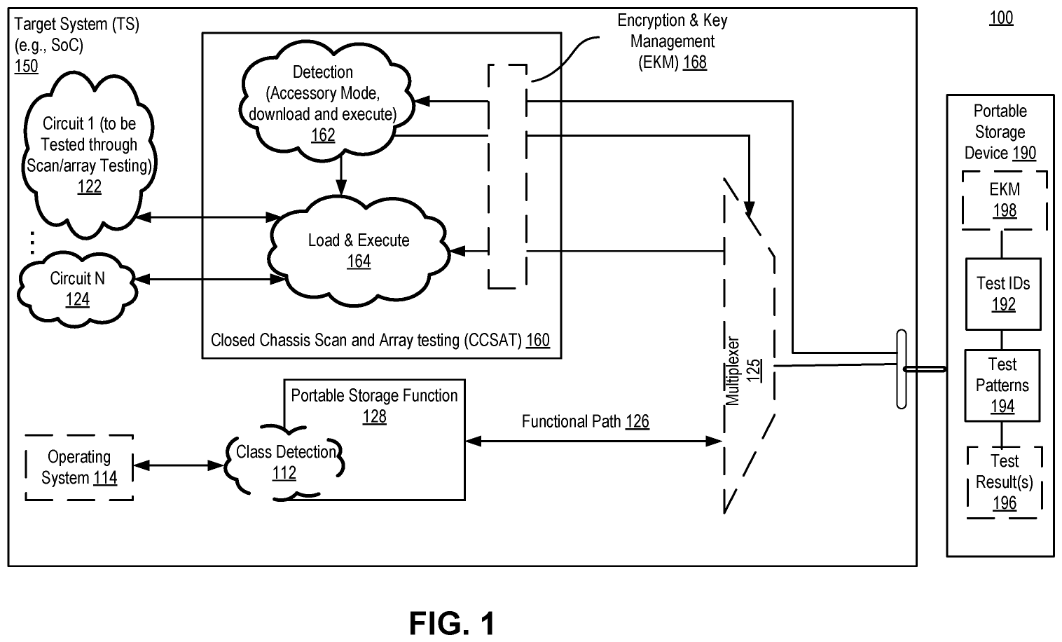

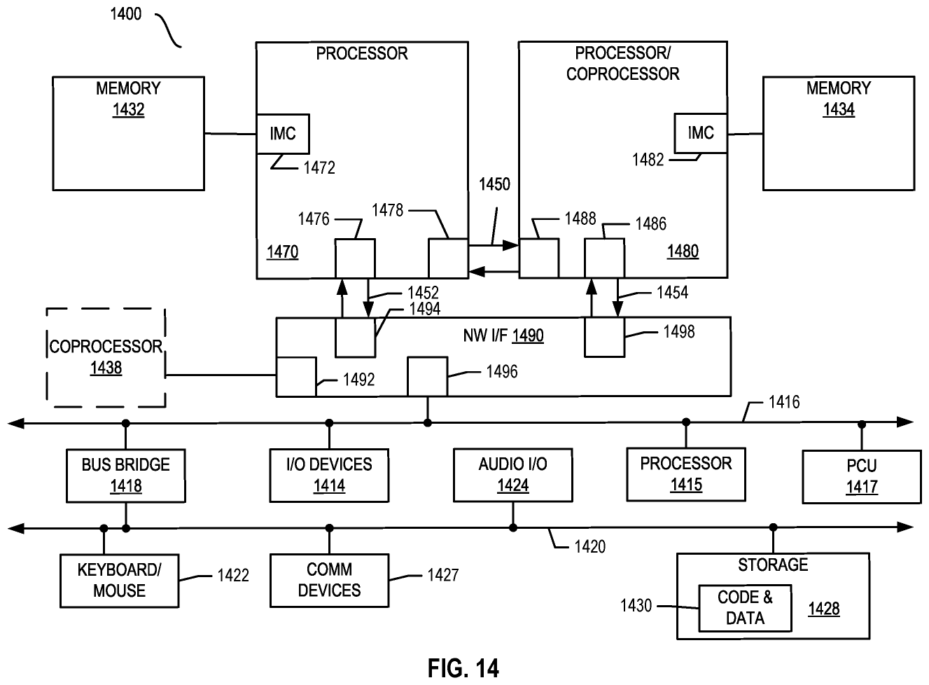

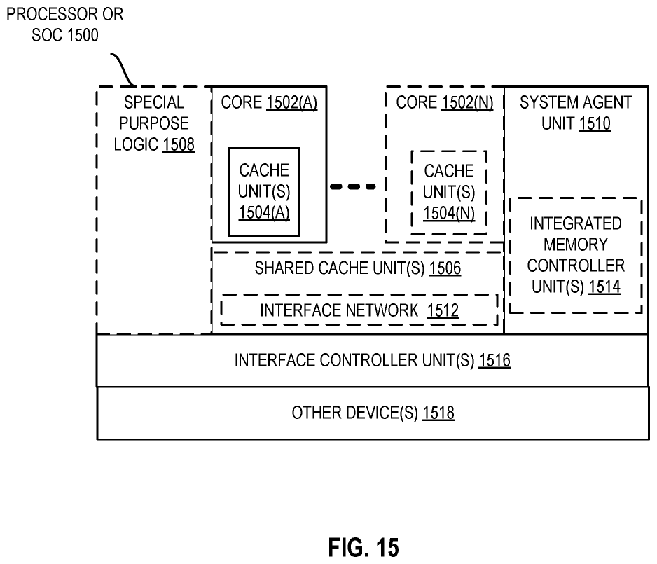

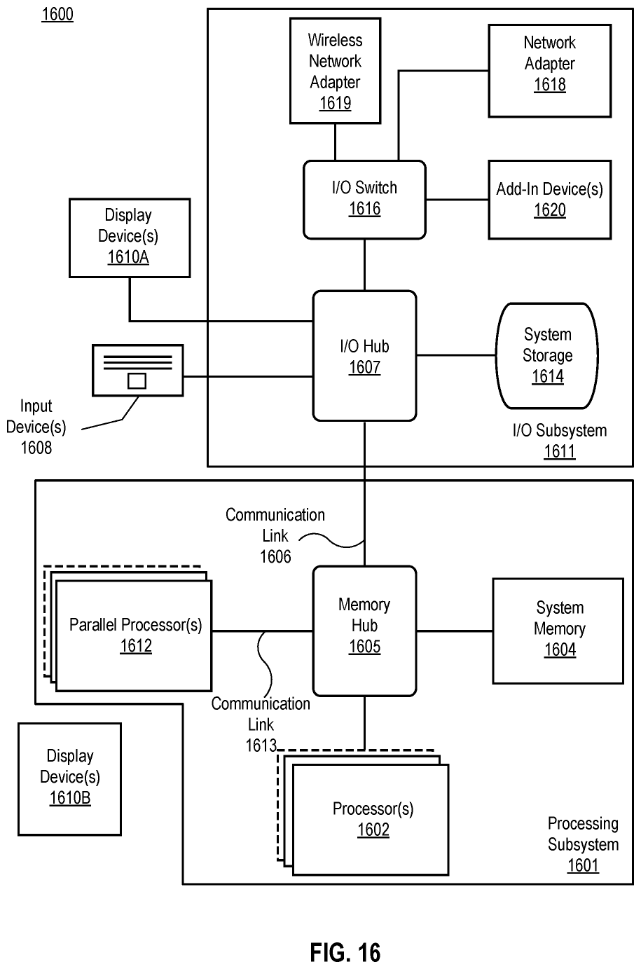

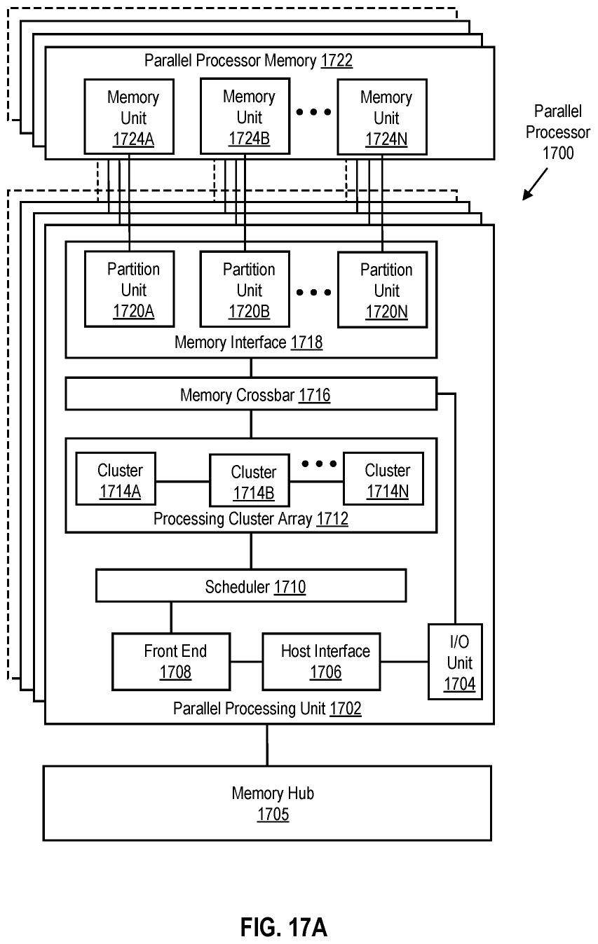

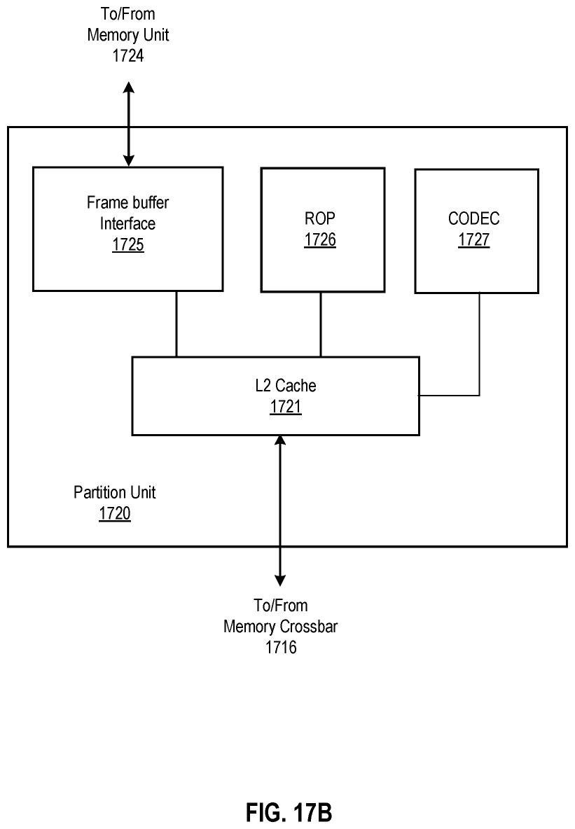

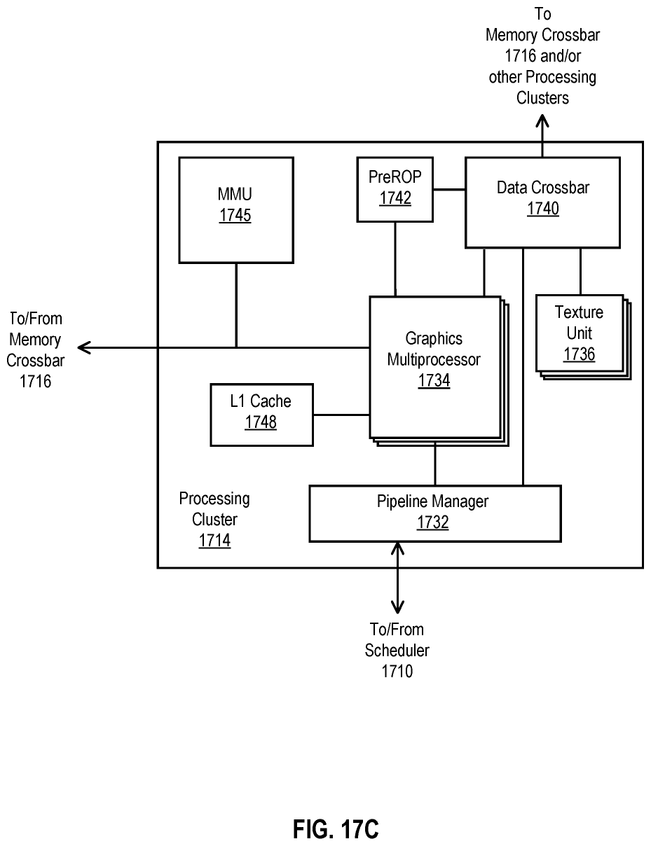

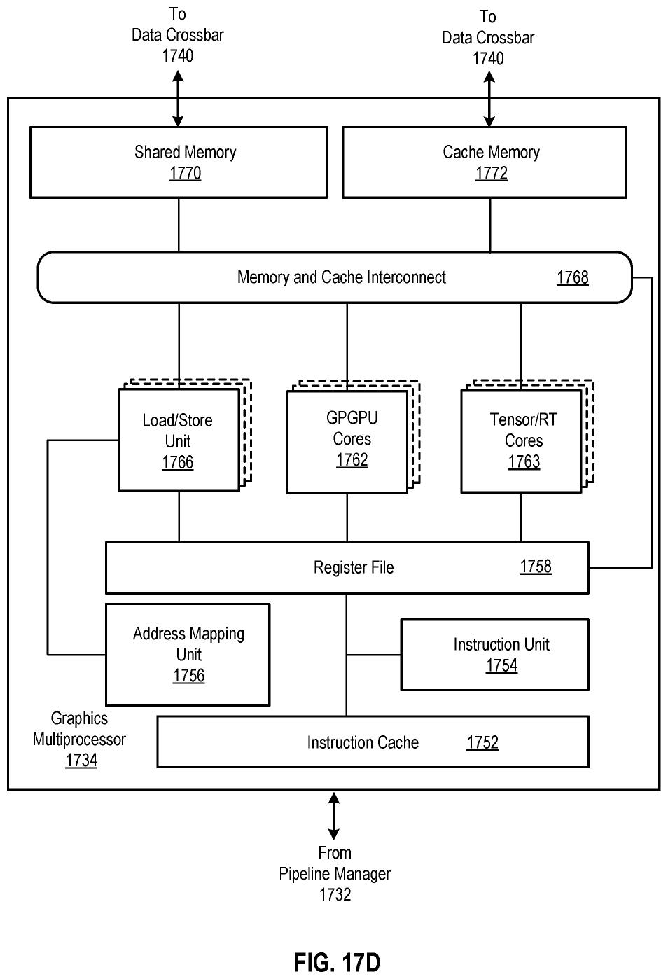

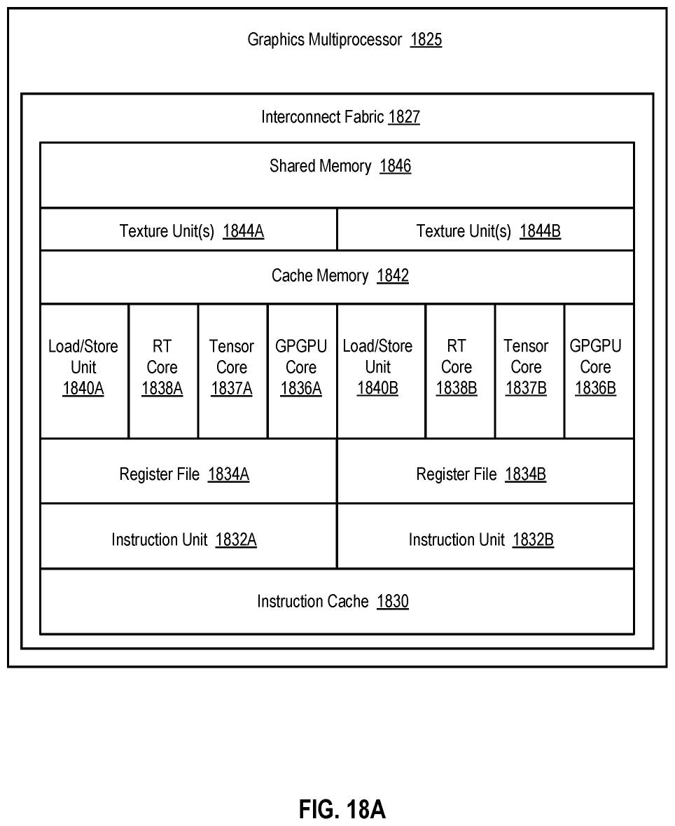

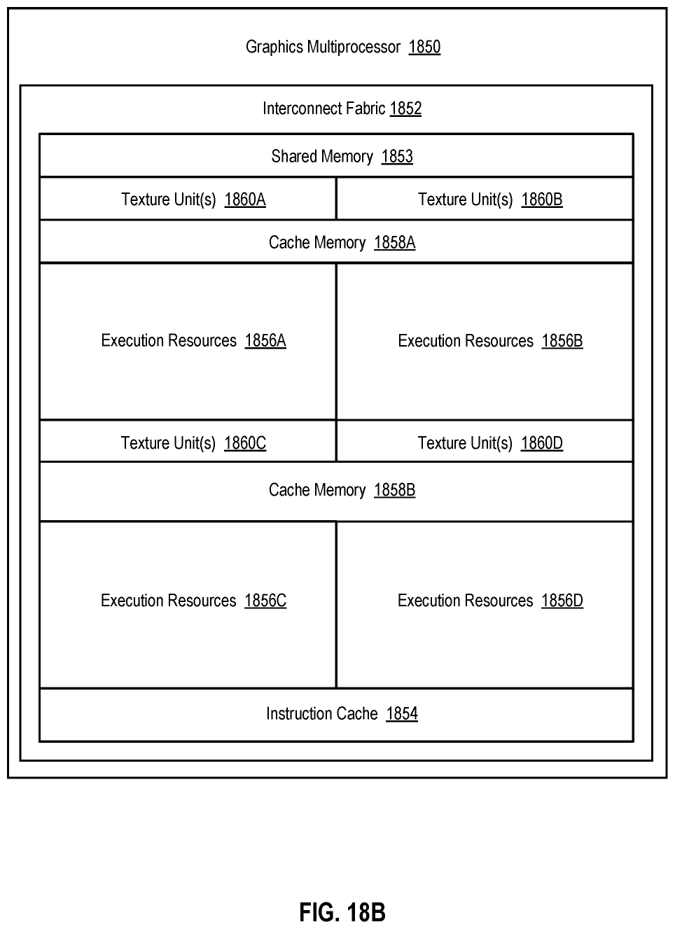

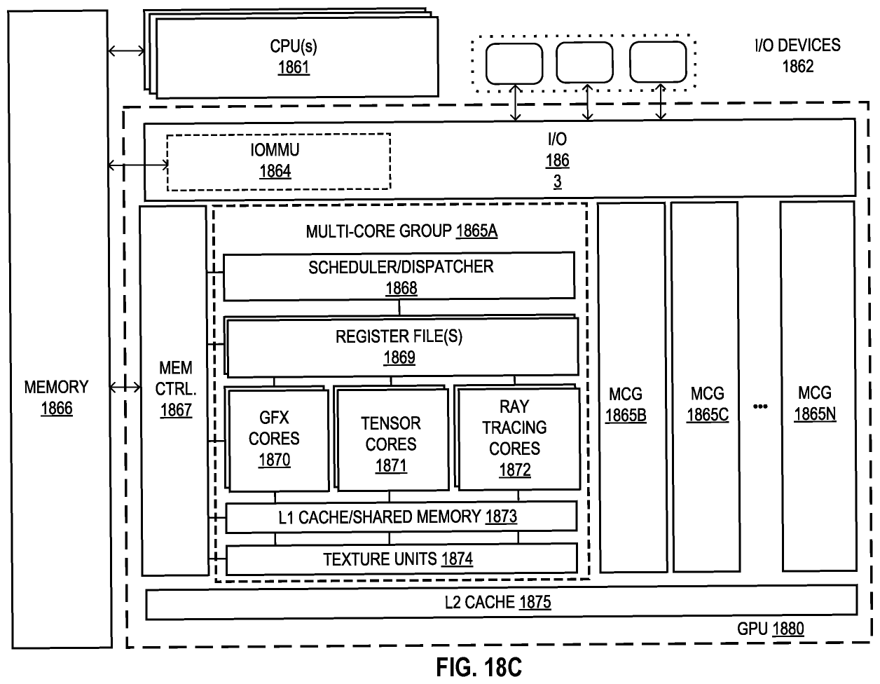

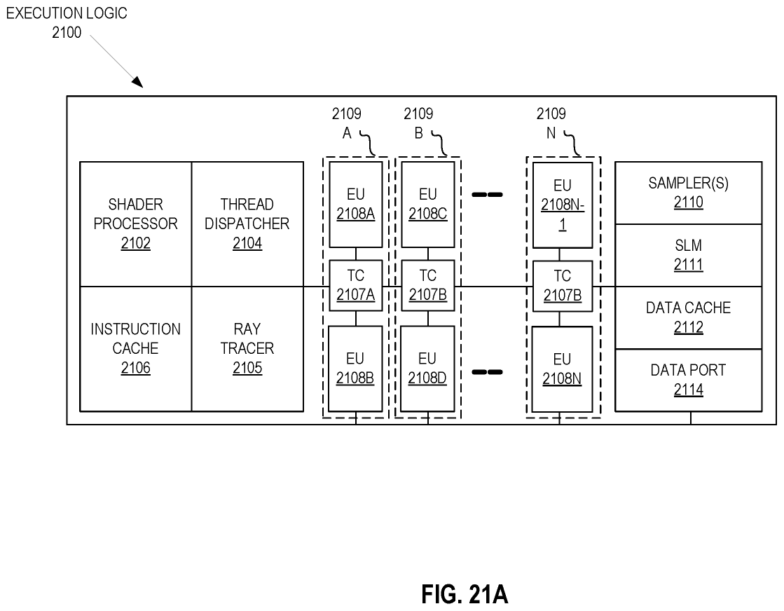

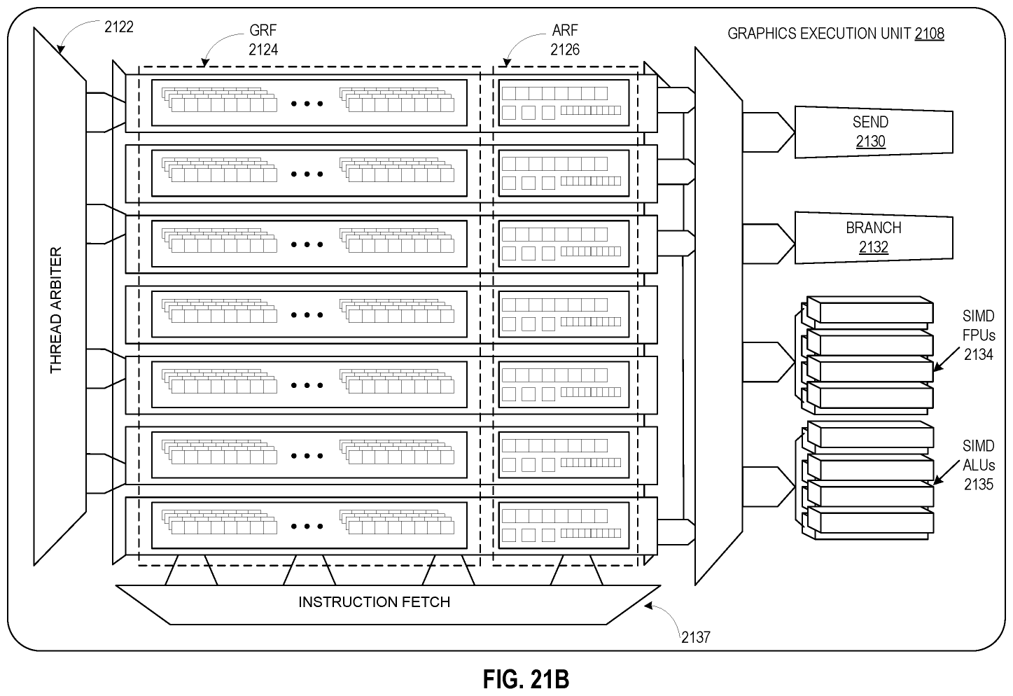

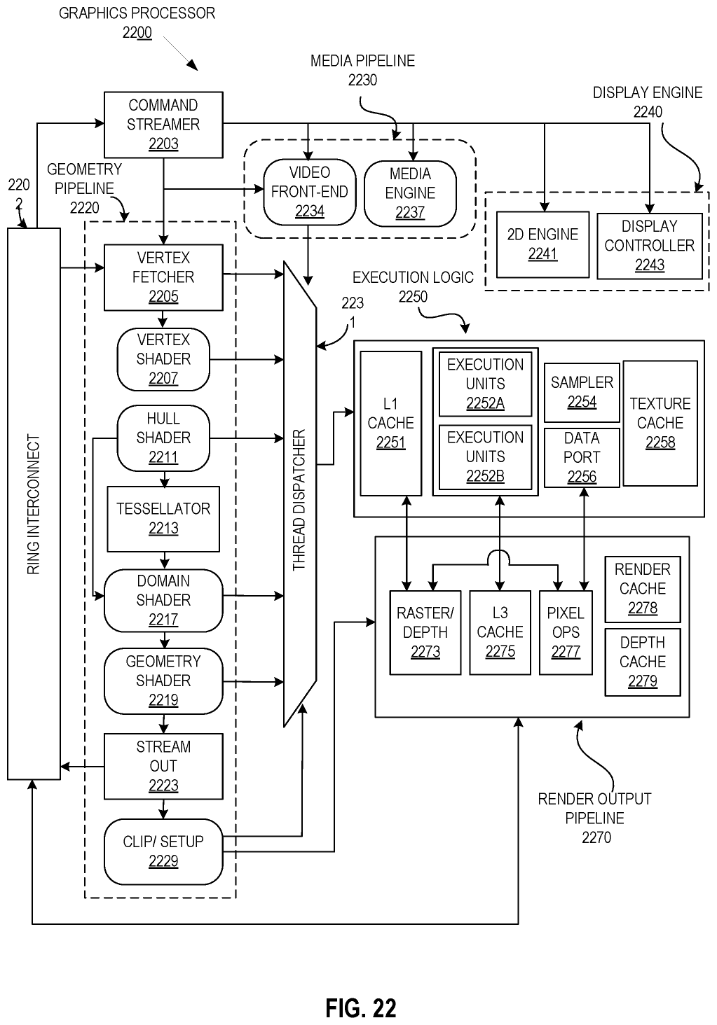

FIG. 1 illustrates a system to detect hardware defects using a portable storage device per some embodiments. The exemplary system 100 includes a target system (TS) 150 and a portable storage device 190. the TS 150 may be a SoC, a System in a Package (SIP), a construction with multiple chiplets, a processor (e.g., CPU/GPU), or another type of processor that includes memory of the SoC/SIP/the construction, a core within the CPU/GPU, or an execution/storage unit within the core. For example, TS 150 may be a whole system (e.g., the ones shown in FIG. 14 (computing system 1400), 16 (computing system 1600), 17A (parallel processor 1700), or processors within (e.g., processor/coprocessor 1415/1470/1438 of FIG. 14, processor/SoC 1500 of FIG. 15, processors 1602/1612 of FIG. 16, parallel processing unit 1702 or graphics multiprocessor 1734 of FIG. 17, graphics multiprocessor 1825 or 1850, GPU 1880 of FIG. 18, execution logic 2100 or graphics execution unit 2108 of FIGS. 21A-B, or graphics processor 2200 of FIG. 22).

Within TS 150, a closed chassis scan and array testing (CCSAT) module 160 detects hardware defects of TS 150. A set of circuits 1 to N is shown at references 122 to 124 as the hardware to be tested. CCSAT module 160 may run scan testing and/or array testing on these circuits. To run scan testing, additional circuitry is added, and it is referred to as a set of scan chains. Each scan chain may include a sequence of registers (e.g., functional registers) that are connected together in a serial fashion to test the circuits. The registers are used to store the values of the circuits' inputs and outputs, and they can also be used to control the circuits' operations. Array testing may include logic gate array testing and/or memory array testing, where the former verifies the functionality of the circuits' logic gates, and the latter verifies the functionality of the circuits forming memory arrays, including SRAM (Static Random-Access Memory), DRAM (Dynamic Random-Access Memory), and other memory types. Embodiments of the disclosure are not limited to a particular type of test to detect circuit defects within a computing system.

CCSAT module 160 includes a detection module 162 to detect a portable storage device 190 from which test content may be loaded, and a load and execute module 164 to load and execute the test content. In some embodiments, an encryption and key management (EKM) module 168 is implemented so that encrypted data loaded from portable storage device 190 (or another external device) may be decrypted, and data to be stored to portable storage device 190 (or another external device) may be encrypted before the storage. While EKM module 168 is shown within CCSAT module 160, it may be implemented elsewhere in TS 150. Note that the detection of the portable storage device 190 may be performed by an entity other than detection module 162, e.g., by an operating system (OS) 114 and/or a USB drive, which detects the portable storage device 190 and determines, through a class detection module 112, the class/subclass of the content within the USB device as discussed in further detail herein below.

TS 150 interacts with portable storage device 190 for hardware testing, and a multiplexer 125 may be included in TS 150 to control the signals from portable storage device 190 to branch off either to CCSAT module 160 or to the corresponding portable storage function 128 that interacts with the portable storage device 190 following the functional path 126. The portable storage function 128 may include (1) a controller to manage communication with the portable storage device 190, (2) a driver to facilitate communication between the controller and an operating system (e.g., OS 114), and/or (3) a protocol unit to define how data is structured, transmitted, and received between TS 150 and portable storage device 190. In some embodiments, a detection class may be defined for the data to be loaded from portable storage device 190 as explained in further detail below.

Portable storage device 190 includes a connector to connect to TS 150, a storage unit (e.g., memory chip/array) to store data, a controller to manage the data and interaction with TS 150. The stored data includes a set of test patterns 194, and the set of test patterns 194 are mapped to one or more test identifiers (IDs) 192, indicating one or more IDs to identify (1) the set of circuits of TS 150, (2) TS 150 itself, or (3) a batch of target systems on which the set of test patterns is to be executed. When the one or more test IDs match one or more ID of the set of circuits of TS 150, TS 150, or a batch of target systems such as TS 150, the corresponding test patterns are executed on the set of circuits of TS 150, TS 150 itself, or the batch of target systems such as TS 150. Otherwise, the test patterns are rejected and won't be executed.

A test ID mapped to a test pattern may include one or more IDs. For example, the test ID may include a die ID corresponding to TS 150. The die ID is assigned to a semiconductor die on a wafer, where a wafer is a thin slice of semiconductor material (usually silicon) on which multiple copies of the same integrated circuit design are patterned. To identify the target system, the test ID may include a SoC/SIP/construction ID, a processor ID (e.g., CPU ID or GPU ID) that identifies the processor's model, features, and capabilities. Furthermore, the ID may be a part ID (or part-ID) that is assigned to a particular model or variant of a computing system (e.g., a processor). Additionally, the test ID may include a silicon stepping ID (also referred to as a stepping code or a stepping level) that is assigned to specific revision or version of a semiconductor device to distinguish between different iterations or revisions of the same underlying design. Additionally, the test ID may include one or more IDs to identify the set of circuits 122 to 124 of TS 150. Furthermore, a test ID may include a combination of two or more of a die ID, a processor ID, a part ID, a silicon stepping ID, one or more IDs to identify the set of circuits of TS 150.

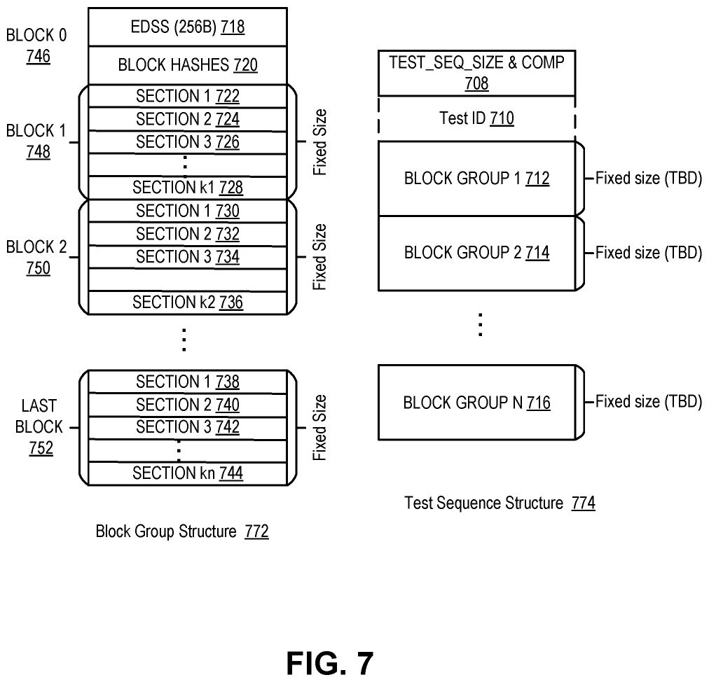

A test pattern may be mapped to one or more IDs that uniquely identify the set of circuits, a target system, or a batch of target systems on which the test pattern is intended to execute. Test IDs 192 is shown as a separate entity in the figure, as the test IDs 192 may be stored separately from test patterns 194 in some embodiments. Alternatively, test patterns 194 may be stored with corresponding test IDs in other embodiments (e.g., FIGS. 7 to 9). Test patterns 194 and test IDs 192 are included in the test content to be loaded to TS 150 for testing hardware defects in some embodiments.

In some embodiments, some or all of the test results from execution of test patterns 194 are stored back to the portable storage device 190 as test result(s) 196. For example, portable storage device 190 may store a test result that identifies a defective circuit, or the test result that is representative for the testing on the type of target system.

In some embodiments, an encryption and key management (EKM) module 198 is included in the portable storage device 190. The EKM module 198 may manage the encryption of test patterns 194, test IDs 192, and/or test result(s) 196. The encryption of the test content provides access security so that even if an unauthorized party gains access to portable storage device 190, they cannot access the test content and determine the stored test patterns, corresponding test ID, and/or test results.

In some embodiments, the encryption of test patterns 194, test IDs 192, and/or test result(s) 196 may be performed prior to storing them to the portable storage device 190. For example, test result(s) 196 may be encrypted by an encryption and key management (EKM) module 168 that is implemented in TS 150 for CCSAT module 160. Additionally, test patterns 194 and/or test IDs 192 may be encrypted (e.g., by the manufacturer of the target system) as they are stored to the portable storage device 190 (e.g., by EKM module 198).

### Test Pattern Execution

CCSAT module 160 may detect portable storage device 190 at a detection module 162 and load test patterns 194 through a load and execution module 164 to run test patterns on circuits 1 to N 122 to 124. The portable storage device 190 may be detected in a variety of ways during different states of TS 150, and three approaches are explained in more detail herein.

### Detection & Loading

The detection and loading approach operates during the boot up state of TS 150. For example, during the boot up process, after the Power-On Self-Test (POST) and initialization of hardware, portable storage device 190 can be detected as the boot device, so that test patterns 194, along with corresponding test IDs 192 in some embodiments, will be loaded from portable storage device 190. The detection at detection module 162 may be triggered by a user action (e.g., a key press during the boot up process) or change of boot up configuration (e.g., change the Basic Input/Output System (BIOS) and Unified Extensible Firmware Interface (UEFI) configuration) of TS 150.

Once test patterns 194 are loaded, integrity check is done to verify that the test patterns are valid. For example, test IDs 192 may be checked to confirm that test patterns 194 is meant to check hardware defects of TS 150. After validation, test patterns 194 are executed by the load and execute module 164 on circuits 122 to 124.

When encryption is implemented on test patterns 194, the content is decrypted first (e.g., through EKM module 168) prior to the execution by the load and execute module 164.

Detection and loading approach are also referred to as download and execute (DnX) approach, and it starts from the boot up of TS 150 and can be initiated once portable storage device 190 is coupled to TS 150 as TS 150 is booted up.

### USB-C Based Loading

In some embodiments, portable storage device 190 includes a Universal Serial Bus (USB) device. Particularly, the USB device supports a Type C connector to couple the USB device to TS 150 and such USB device may be called a USB-C device or USB Type C device. As known in the art, the USB protocol is defined by the USB Implementers Forum (USB-IF) and includes USB Type-C connector since 2014. The USB-C device supports a variety of modes, and the USB-C Power Delivery (PD) alternate mode and debug accessory mode are of interest for hardware defect detection disclosed herein. One difference from the detection and loading approach is that the USB-C based loading may operate during the normal operational state of TS 150 as well as the boot up state of TS 150.

### USB-C Power Delivery (PD) Alternate Mode

The USB device with the Type C connector supports Power Delivery (PD) alternate mode, which allows the corresponding USB Type-C port to carry not only USB data and power but also other types of data and protocols, such as DisplayPort, HDMI, or Thunderbolt, so that the USB Type-C port can be used for different purposes, including transporting test patterns 194.

A specific command may be initiated to fetch test patterns 194, along with corresponding test IDs 192 in some embodiments, from portable storage device 190 by the load and execute module 164. After the test patterns 194 are loaded, the validation and decryption may be performed similarly as in the detection and loading approach.

The loading may happen during the TS 150 boot up or normal operation state. During the normal operation state of TS 150, a processor (e.g., a CPU/GPU core) of TS 150 becomes available to run test pattern and the PD alternate mode has no higher priority tasks to perform, then test patterns 194 may be fetched through the specific command and be executed to detect hardware defects.

### USB-C Debug Accessory Mode

In some embodiments, a USB Type C device may operate in the debug accessory mode, where the USB Type C device may provide detailed diagnostic information to a connected TS 150. A specific command may also be initiated to fetch test patterns 194, along with corresponding test IDs 192 in some embodiments, from portable storage device 190 by the load and execute module 164. After the test patterns 194 are loaded, the validation and decryption may be performed, similar as the USB device in the USB-C PD alternate mode.

### OS/USB Driver Based Loading

USB-IF defines several USB classes for various types of USB devices to ensure interoperability and compatibility between different USB devices and hosts. USB classes include base classes and subclasses to categorize and standardize the functionality and communication protocols for specific types of USB devices.

A base class represents a broad category of USB devices. For example, USB-IF defines base class for Diagnostic Device Class (DIAGNOSTIC) with Hex Code 0xDC. Under each base class, a set of subclasses provides specific definition for various device types. A set of subclasses may be defined for detecting computer hardware defects, e.g., a subclass with Hex Code 0x09, with defined protocol code, such as Hex Code 0x00 for undefined, 0x01 for scan and array encrypted testing, 0xFF for vendor defined testing. By defining a specific subclass for a specific test pattern (e.g., one under base class DIAGNOSTIC with Hex Code 0xDC), the subclass may be recognized by any standard compliant USB devices and hosts, and the loading and execution of such test pattern may be coordinated among different manufacturers and make the hardware defect detection more efficient.

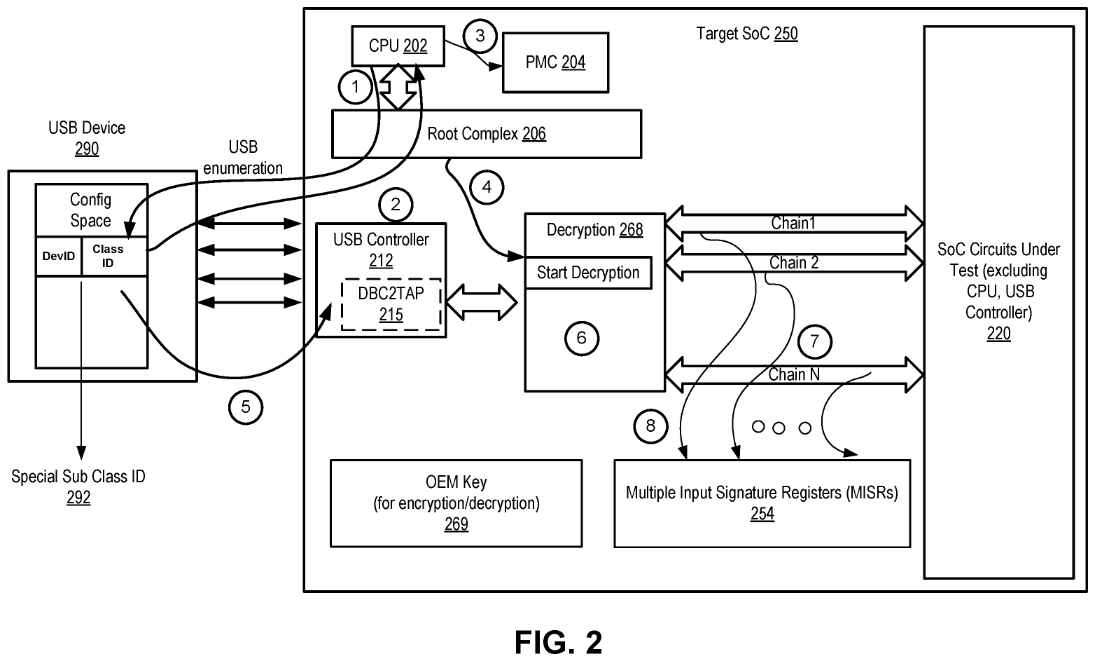

FIG. 2 illustrates a system to detect hardware defects using a USB device per some embodiments. The target system is a target SoC 250, and USB device 290 stores one or more test patterns. The SoC circuits under test are shown at reference 220, and they exclude circuits within CPU 202 and USB controller 212, both of which are involved in loading and execution the test patterns from USB device 290.

For the test patterns in USB device 290, a configuration space (e.g., Peripheral Component Interconnect Express (PCIe) configuration space) stores configuration of the test patterns. In addition to the device ID and class ID mapped to a test pattern, a special subclass ID 292 (e.g., under base class 0xDC) may be specified for a test pattern. Cycles 1 to 8 indicate the sequence of operations to be performed per some embodiments.

At Step 1, an OS (not shown) of target SoC 250 and/or a USB controller 212, which implements a USB driver to enable the OS to communicate with the USB device 290, enumerates the USB device 290 using a processor (e.g., CPU 202) by reading the device ID, Class ID, subclass ID from the Configuration space of USB device 290 for test patterns (e.g., test patterns 194). When PCIe protocol is used for communication between the USB device 290 and target SoC 250, the reading goes through a root complex 206. The subclass ID 292 from the USB device 290 informs the USB driver and/or the OS that test patterns from the USB device 290 are to be loaded to Target SoC 250, and the USB driver or the OS will coordinate the execution of the test patterns on the target SoC 250. In some embodiments, the special subclass ID 292 for the test patterns is detected by the class detection module 112.

The USB controller 212 may include a DBC2TAP 215 in some embodiments. DBC2TAP 215 is a USB debug class controller to test access port (TAP) protocol converter, and converts data pulled from USB device 290 into the Joint Test Action Group (JTAG) protocol that includes Test Access Port (TAP). The conversion is necessary in these embodiments when a target system such as target SoC 250 utilizes JTAG TAP interfaces for test (e.g., scanning/array testing) and a variety of registers within the target system are to get programmed through the JTAG protocol to perform structural testing.

At Step 2, the OS and/or the USB driver receives the test information from USB device 290 and confirms whether it matches the values stored at target SoC 250. For example, the test information from USB device 290 includes subclass ID 292 of the test patterns stored in USB device 290, and Step 2 confirms that the subclass ID 292 matches an ID of target SoC 250. If not, the test patterns are not executed on target SoC 250. If yes, then USB controller 212 recognizes USB device 290 as containing the test patterns to be loaded and executed. In addition, USB controller 212 will now follow a sequence of steps to carry out the testing.

At Step 3, the USB controller 212, through CPU 202, checks the operational state of target SoC 250, e.g., through checking Performance Monitoring Counter 204. If a processor is available to run the test patterns (e.g., when one or more cores are idle, while another core is running to execute tasks for OS/USB driver and the USB controller to which USB device 290 is attached to), then the processor is triggered to run the test patterns.

At Step 4, the test patterns are loaded and decrypted at decryption module 268. The decryption may be performed using one or more private keys of target SoC 250. For example, the private keys may be OEM keys 269. At Step 5, the integrity of the test patterns is checked by the USB controller 212. Steps 4 and 5 may be run simultaneously or in the opposite order, depending on what has been encrypted and how encryption is done.

At Step 6, the decryption is done, and the decrypted test patterns are ready to be run on the SoC circuits 220. The running of the test patterns includes scanning through a set of scan chains at Step 7, where the set of scan chains are connected/coupled to a set of registers such as Multiple Input Signature Registers (MISRs) 254 at Step 8. The MISRs 254 may sequentially capture signatures generated from the SoC circuits 220 through the testing and compare against expected values and determine whether a circuit is defective. Note that while only scan chains are shown for illustration, similar operations may be performed for array testing such as logic gate array testing and/or memory array testing.

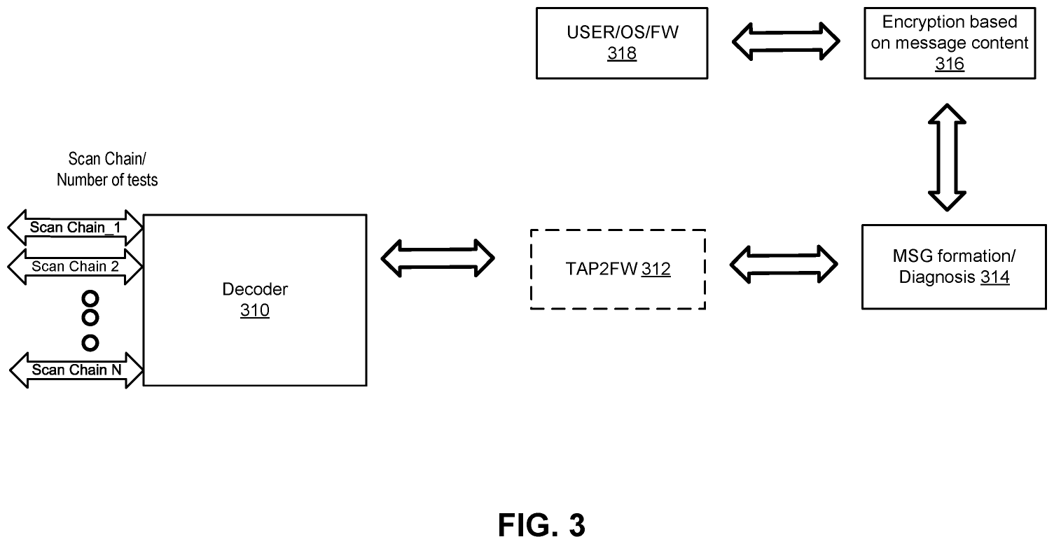

Through any of the three approaches, a portable storage device may be detected by a target system, and the test patterns stored in the portable storage device may be loaded to the target system, and the test results may be collected. FIG. 3 illustrates test result collection and storage per some embodiments. At a decoder 310, the test results from testing a target system are analyzed to determine which, if any scan chain is failed. Based on the scan chain failure information, decoder 310 can determine one or more partitions for which a particular scan chain is failing so the circuits in the failing partitions are to be determined as defective. For example, when scan chain 2 fails, and scan chain 2 corresponds to the partitions of a PCIe Gen6 controller with specific Bus, Device and Function Number (BDF), one or more of the PCIe Gen6 controller circuits are then deemed defective. Information about the determination and corresponding data (including the identification information of the defective circuits/partition) are provided to the test access port to firmware (TAP2FW) module 312 in some embodiments. The TAP2FW module 312 is utilized to convert the data from JTAG (TAP) format to data in a firmware protocol, and such data may be further analyzed.

The information is stored as one or more messages through a message formation and/or diagnosis module 314. The one or more messages are then encrypted based on the message content at module 316. The encrypted content is then provided to a user, the OS, or software/firmware at module 318 so further triage may be performed. For example, if the defects are structural/aging related, the target system may be returned to the corresponding semiconductor manufacturer. If, however, if the defects are logical, the target system should not be returned but investigated locally by the OEM that implements the target system into their system as the logical defects should be addressed by the OEM instead.

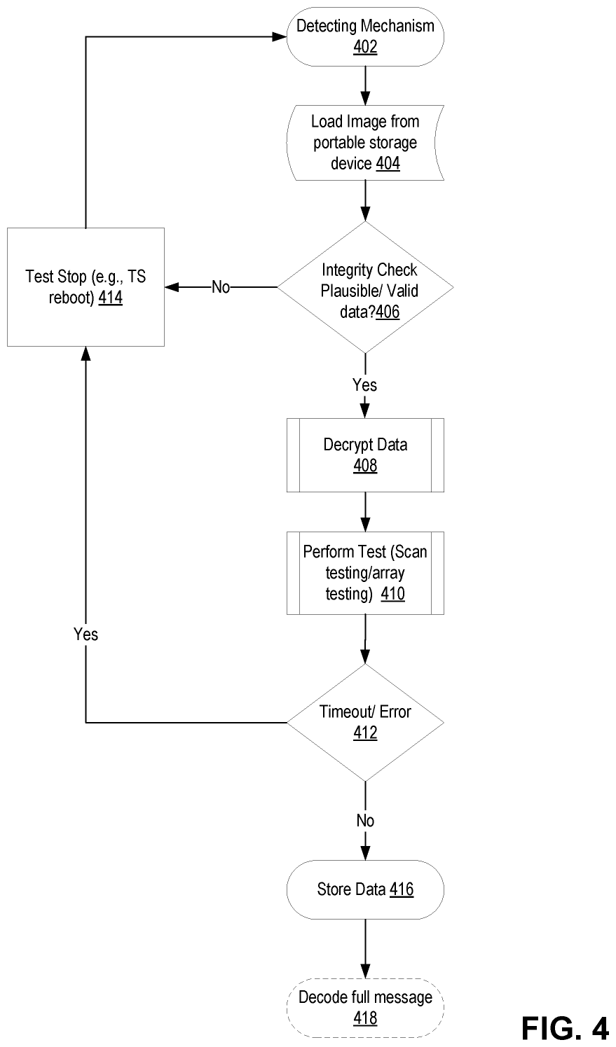

FIG. 4 illustrates a flow diagram to show the operations to detect hardware defects using a portable storage device per some embodiments. The operations may be performed at a target system such as TS 150 or target SoC 250.

At reference 402, the detecting mechanism is determined. The detect mechanism may be one of three approaches discussed herein above. At reference 404, an image is loaded from a portable storage device. The image includes the test content, which includes test patterns and corresponding test IDs (e.g., test patterns 194 and test IDs 192).

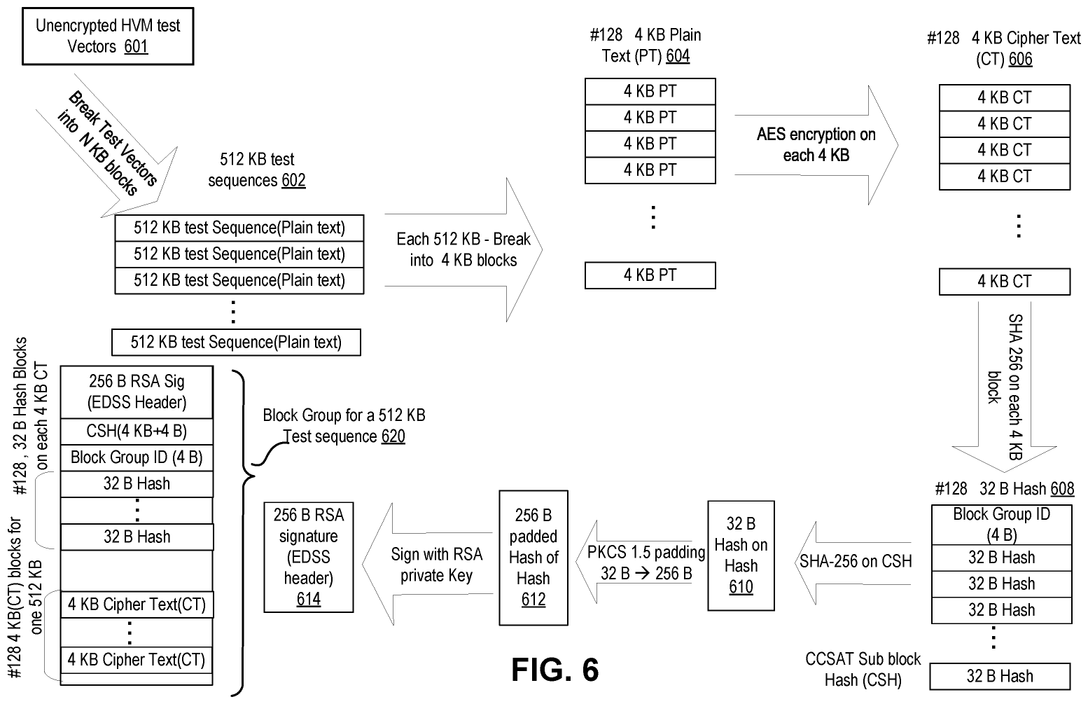

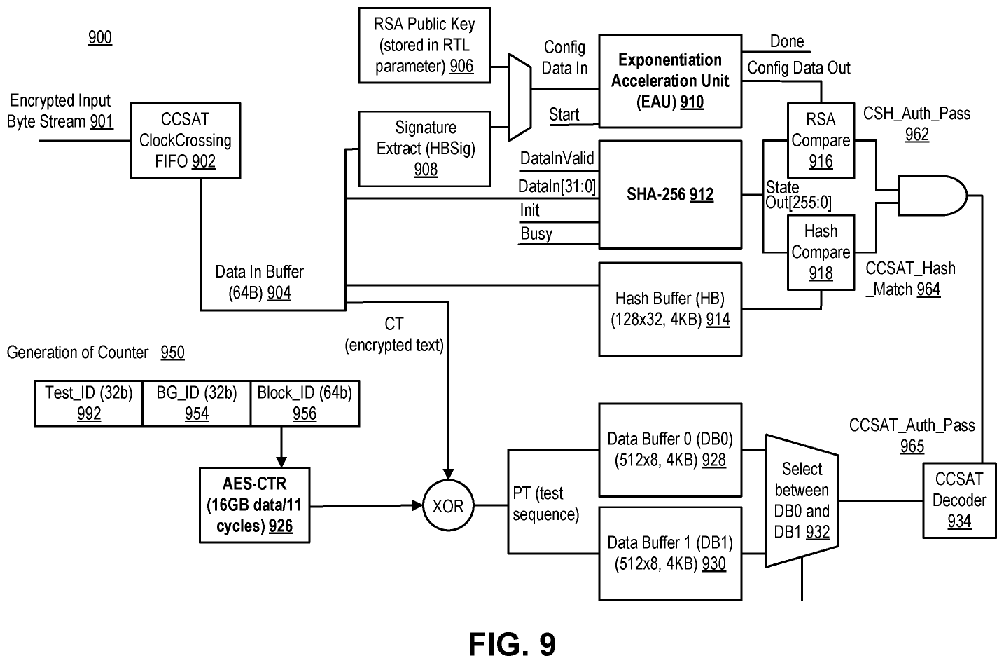

At reference 406, it is determined whether the test content passes the integrity check, e.g., whether the test content is valid/plausible, and the integrity check may be simple ones through encryptions/decryption such as parity bits, file verification tools, error-correcting codes (ECC) or more complicated checksums and hash functions such as message digest algorithms (e.g., MD5) and/or secure hash algorithm (SHA). See FIGS. 6 and 9 for examples of encryption and decryption performed for integrity check. If the integrity check fails, the flow goes to reference 414, and the test stops. In some embodiments, the target system reboots upon the test stops. After the test stops, the flow goes back to reference 402.

If the integrity check passes, the decrypted image as data is then loaded at reference 408. The decrypted data including the test patterns is then executed at reference 410, where scan testing and/or array testing may be performed. The test may encounter issues (e.g., stuck at execution for some reason), or the test may time out after a duration at reference 412. When that happens, the flow goes to the test stop at reference 414.

Otherwise, the test continues, and the test results are stored as data at reference 416. The test results may be stored at the target system, the portable storage device, or another storage (e.g., Cloud storage). Multiple test patterns may be executed following the flow, and the total test results may be stored as a software image, which may be decoded. The decoding may be done by the target system and initiated by a user such as the semiconductor manufacturer or OEM. Note that the decoding is not necessarily done at the test site. For example, the image may be uploaded to cloud (e.g., with proper encryption), so the decoding and diagnosis based on the test results can be done at where the storage/processing resources are readily available and such remote diagnosis takes advantage of the convenience of testing on site using a portable storage device while maintains the efficiency of diagnosis by utilizing remote available storage/processing resources.

### Operations and Configuration of Portable Storage Device

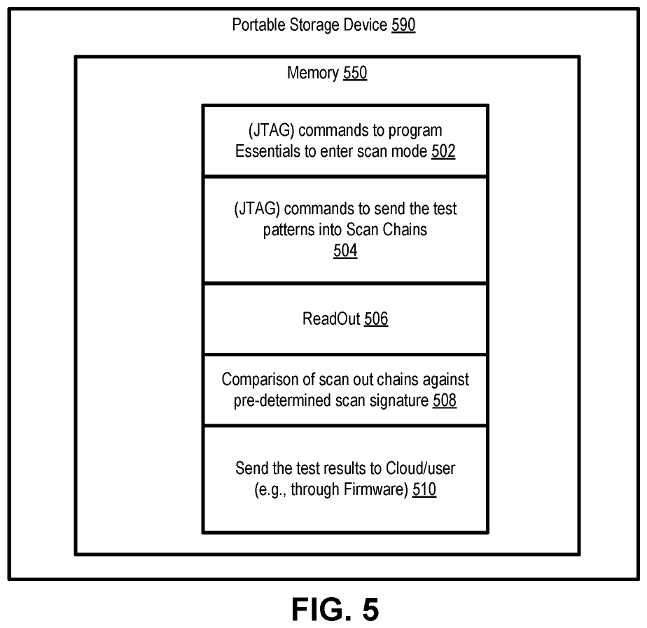

While the operations at a target system are discussed in detail herein above, this section provides further detail about the operations at a portable storage device. FIG. 5 illustrates high level code segments corresponding to operations to be performed to detect hardware defects using a portable storage device per some embodiments.

The portable storage device 590 includes memory 550, which may store a code image that includes one or more of the following code segments to support the hardware defect detection operations. One code segment 502 is a set of commands to program circuits/logic for hardware defect detection in the target system. Such circuits/logic include one or more of scan clock controller, scan reset controllers, Memory Built-In Self-Test (MBIST) controllers, Joint Test Action Group (JTAG) test data registers. In some embodiments, the set of commands complies with JTAG standards and are referred to as JTAG commands. This code segment at reference 502 may be executed once the target system first loads the image from the portable storage device 590.

After the code segment 502 is executed, the next code segment 504 is a set of commands to send the test patterns into scan chain. The commands may include a series of BIOS/UEFI configuration command in the detection and loading approach, the specific command to fetch test patterns in the USB-C based loading (in alternate mode or the debug accessory mode), and commands to interact with the OS/USB driver in the OS/USB driver based loading approach. Using these commands, the test patterns are applied to a set of scan chains for a number of clocks, and the number of clocks may be configured to set a timeout as used at reference 412.

The next code segment 506 is a set of commands to apply to read out the response from scan chain testing. The response from the scan chain testing is then applied to a set of MISRs and the response is compared against pre-determined scan signature through a set of commands in code segment 508. The comparison determines whether there is a test failure and/or timeout (see reference 412).

The next code segment 508 corresponds to references 416 and 418, and the commands in this code segment cause the test results and related messages to be sent to a user or cloud. In some embodiments, firmware is implemented to cause the test results and related messages to be stored at the target system, the portable storage device, or another storage (e.g., Cloud storage).

### Encryption of Test Patterns and Test Results

As explained herein above, encryption may be applied to test content, including test patterns, corresponding test IDs, and test results to provide access security on the portable storage device. Encryption may be applied even more broadly for the security of hardware defect detection in some embodiments. For example, the whole memory 550 may be encrypted so that even if an unauthorized party gains access to portable storage device 590, they cannot access the commands to implement embodiments herein as well as the test content and determine the stored test patterns, corresponding test IDs, and/or test results.

FIG. 6 illustrates encryption of test patterns to detect hardware defects per some embodiments. The test patterns may be encrypted prior to being stored in a portable storage device as well as when they are stored in the portable storage device. The test patterns provided by a semiconductor manufacturer include unencrypted high-volume manufacturing (HVM) test vectors 601 in some embodiments. The HVM test vectors include one or more of functional test patterns, stress test patterns, boundary scan test patterns, scan chain initialization patterns, clock and timing patterns, data patterns, functional mode and mode switching patterns, power and voltage test patterns, input and output patterns, and Built-In Self-Test (BIST).

The HVM test vectors 601 are broken into N kilobytes (KB) blocks. In this example, each of the N KB blocks is a 512 KB test sequence, as shown as 512 KB test sequence 602. Since they are unencrypted, they are referred to as plain text (PT). Each of the 512 KB plain text test sequences is then broken into 128 4 KB PT blocks 604.

Then each 4 KB PT block is encrypted into cypher text (CT) block using Advanced Encryption Standard (AES) and the 4 KB CT blocks are shown at reference 606. The AES encryption may be performed with keys of 96 bits, 128-bit, 192-bit, 256-bit, or another bit width.

Then secure hash algorithm (SHA) is applied to each 4 KB CT blocks to form 128 hashes of 32 bytes (32 B hash) as shown at reference 608. A hash may also be referred to as a digest value in some embodiments. In some embodiments, the applied SHA is SHA-256 as shown in the figure. The 32 B hashes are also referred to as CCSAT sub block hash (CSH) as they are used in CCSAT testing (e.g., CCSAT module 160). The CSHs are identified with block group IDs to specify the order of the test sequences and within test sequences. The block group ID takes 4 bytes in some embodiments as shown.

On each of the 32-byte (32 B) hashes, the same SHA-256 (or a different SHA in an alternative embodiment) is applied to generate a hash on hash (also referred to as hash-of-hash) on all 128 32-byte hashes at reference 610. The 32-byte (32 B) hash on hash is then padded, e.g., through a Public-Key Cryptography Standards (PKCS) padding such as PKCS 1.5. The PKCS padding converts the 32 B hash on hash into a 256-bytes (256 B) padded hash on hash as shown at reference 612. The padded hash on hash 612 is then signed by a Rivest-Shamir-Adleman (RSA) private key to produce a 256-bytes RSA signature 614, which is also referred to as an Enterprise Digital Signature Service (EDSS) header.

For each plain text test sequence of 512 KB, a block group is built as shown at reference 620. The block group includes the EDSS header of 256 bytes, along with the CSHs, the block group IDs, and the CT blocks. These block groups form the encrypted test patterns to be loaded and executed on a target system.

FIG. 7 illustrates a block group structure and a test sequence structure after encryption per some embodiments. The block group structure 772 may implement the block group 620, where Block 0 at reference 746 includes the EDSS header 718 (corresponding to the RSA signature of the block group 620) and a set of block hashes 720 (corresponding to the CSH, the block group ID and the 32 B hashes). Then more blocks follow, and a block may include a number of sections, each of which may include the cypher text shown in FIG. 6, and/or also commands such as ones to initiate a test pattern, or JTAG/TAP commands discussed relating to FIG. 3. The sections may have the same fixed size, but blocks may have different number of sections, indicated by the variable Kn. As shown, Block 1 to last block are at references 748 to 752, where Sections 722 to 728 are included in Block 1, Sections 1 to k2 at references 730 to 736 are included in Block 2, and Sections 1 to Kn at references 738 to 744 are included in the last Block 752.

The block groups from the test sequences (e.g., the 512 KB test sequences 602) may form a test sequence structure 774, where a test sequence after encryption includes a header at reference 708, indicating the test sequence sizes and complement information. For example, the test sequence size may be 40 bytes, and the value is 00101000 and the complement of the size value is 1101 0111. The encrypted test sequence may also include a test ID 710 in some embodiments. As discussed herein above, a test ID may be a die ID, a processor ID, a part ID, or a silicon stepping ID to identify the intended target system(s) for the test patterns. The test ID 710 may be not only a single ID as enumerated, but also a combination of two or more of a die ID, a processor ID, a part ID, and a silicon stepping ID. The encrypted test sequence further includes a set of block groups, such as ones following the block group structure 772 (e.g., block group 620). A test sequence following the test sequence structure 774 may then additionally include a set of block groups 1 to N at references 712, 714, to 716.

In FIG. 6, a specific sequence of encryption algorithms and operations are shown to form block group 620, which may form one block group of block groups 1 to N at reference 716 of FIG. 7. Some embodiments may implement a subset of the encryptions, and others may implement additional ones based on availability of hardware/software support and/or the level of authentication requirement. For example, when the required authentication level is low and/or encryption hardware/software is insufficient, some embodiments may implement only the AES encryption without SHA encryption, SHA encryption without hash on hash, another version of PKCS padding or no padding at all. On the other hand, when required authentication level is high and/or encryption hardware/software is readily available, more encryptions may be implemented to ensure no authorized party may access to the test vectors 601, even if they gain access to the portable storage device.

While HVM test vectors 601 are used as examples of test patterns, other test patterns and test results may use similar encryptions to provide access security. For test patterns, the encryption operations may be done by either the portable storage device (e.g., the EKM module 198) when the test patterns are stored to a portable storage device, or by an apparatus operated by an owner of the test patterns (e.g., a semiconductor manufacturer) prior to the test patterns being stored to the portable storage device. Similarly, for test results, the encryption operations may be done by either the portable storage device (e.g., the EKM module 198) when the test results are stored from a target system to the portable storage device, or by the target system (e.g., the EKM module 168) prior to the test results being stored to the portable storage device.

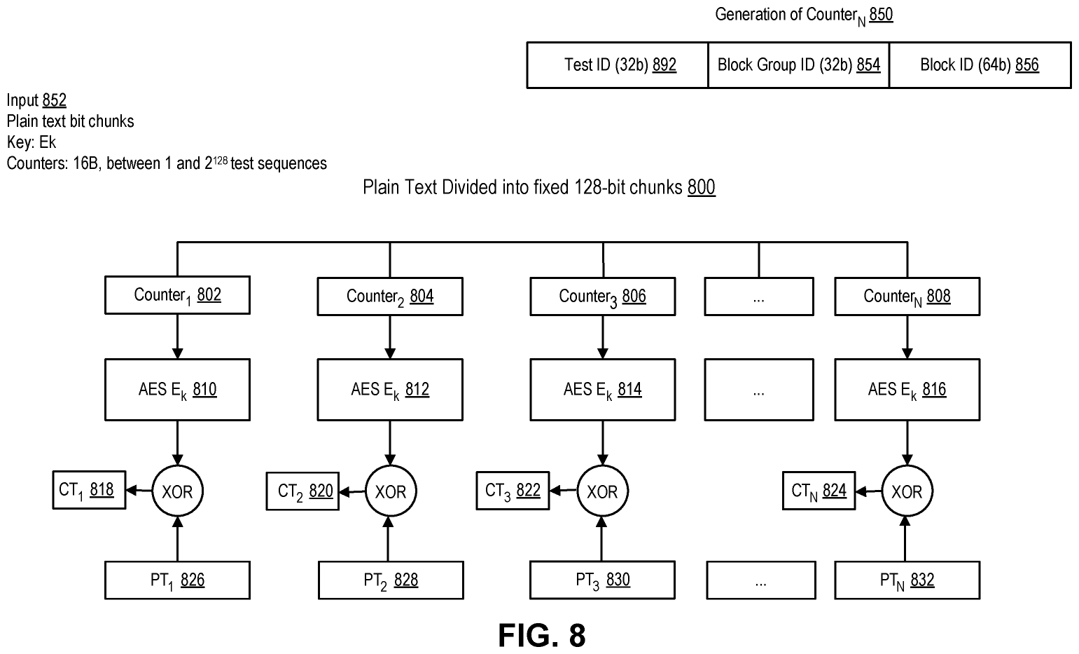

Note that block group ID is included in the block group of the encrypted test patterns to ensure that the proper order of test sequences is followed in loading and execution. It is preferable that additional IDs may be embedded so only one or more IDs to identify the set of circuits to be targeted, a target system, or batch of target systems may run the encrypted test patterns. FIG. 8 illustrates Advanced Encryption Standard (AES) encryption of test patterns for a system to detect hardware defects using a portable storage device per some embodiments.

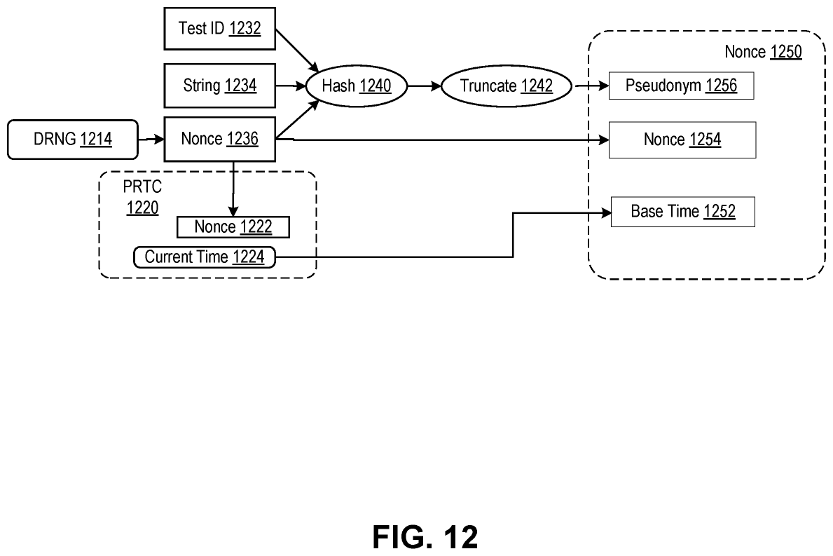

The AES encryption operates in counter mode in these embodiments. The AES counter mode, referred to as AES-CTR, uses a counter value for generating a unique encryption key for each block of plaintext. This counter value is combined with a nonce (a number used only once) to produce a unique value for each block. In some embodiments, the counter is generated based on a test ID 892 as well as block group ID 854 (to identify the block group that a block belongs) and block ID 856 (to identify the block in the block group) as shown at reference 850. For example, the counter may be generated through hashing (and optionally truncation) the test ID 892, block group ID 854, and/or block ID 856. While specific bit widths of these IDs are shown, they are examples and other embodiments may use these IDs with a different bit width. In addition/alternative, the nonce may be generated using a test ID as well (see FIG. 12).

As discussed herein above, a test ID may include one or more of a die ID, a processor ID, a part ID, or a silicon stepping ID to identify the intended target system(s) for the test patterns. The test ID 892 may be not only a single ID as enumerated, but also a combination of two or more of a die ID, a processor ID, a part ID, and a silicon stepping ID. Through embedding the test ID 892, the AES encrypted data may identify one or more target systems to which the test patterns target.

In AES encryption, input 852 includes (1) a stream of plain text bit blocks of fixed size of N KB bits (e.g., the 512 KB test sequences 602), (2) counter values at references 802 to 808, which are generated as shown at reference 850, and (3) AES keys Ex 810 to 816 (k goes from 0 to 255 in one embodiment for the 128 counters, each for a 128-bit chunk). In this example, a 4 KB plain text (PT) block is divided into fixed 128-bit chunks 800, and the chunks are shown as PTs 826 to 832, the counter values at references 802 to 808 applies to AES keys Ek at references 810 to 816, and exclusive OR (XOR) operates on the resulting values and corresponding PT blocks (the plain text bit chunks) at references 818 to 824 and generates cypher text (CT) bit blocks at references 818 to 824.

With the AES encryption, the stream of PT bit blocks from a set of test patterns to be run on a set of target systems is converted to a stream of CT bit blocks, each is marked with test ID 892 to identify the set of target systems to be tested. Such encryption ensures that only the matching target systems will execute the test patterns.

### Decryption of Test Patterns and Test Results

The encrypted test patterns shown in FIGS. 6 to 8 need to be decrypted before being executed at a target system. The target system may implement hardware/logic to decrypt the test patterns. Similarly, when test results are encrypted (e.g., by EKM module 168), the test results need to be decrypted so that they may be analyzed as well. FIG. 9 illustrates decryption of a byte stream for hardware defect detection using a portable storage device per some embodiments. The decryption is performed through three hardware circuits, an AES-CTR module at reference 926, a SHA-256 module at reference 912, and an Exponentiation Acceleration Unit (EAU) at reference 910, all of which are shown with bold font.

Hardware circuits for Decryption

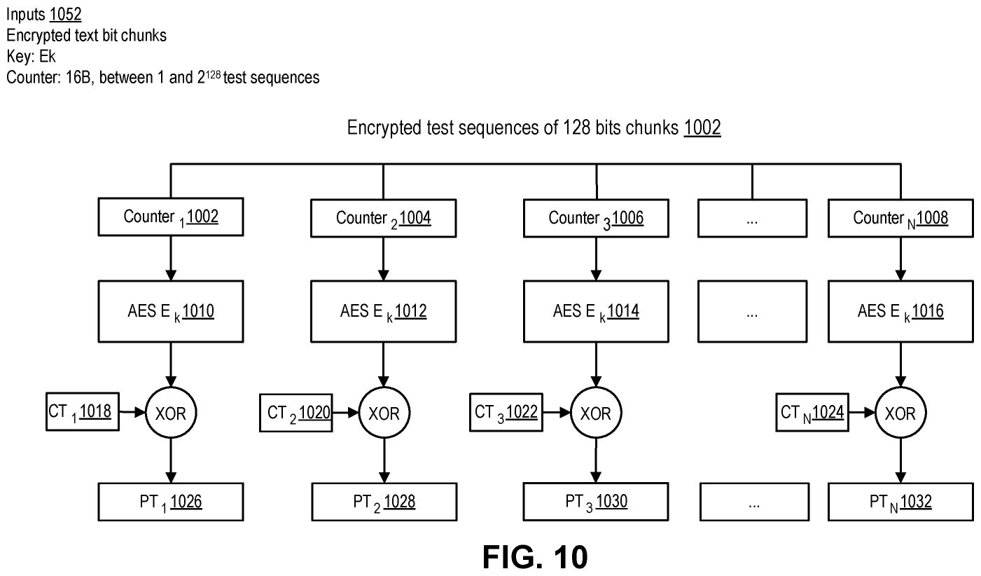

The AES-CTR module 926 is a symmetric block cipher that is standardized to encrypt and decrypt data. In some embodiments, the AES-CTR module 926 may perform the encryption shown in FIG. 8 and/or the decryption show in FIG. 10. FIG. 10 illustrates Advanced Encryption Standard (AES) decryption of encrypted data for a system to detect hardware defects using a portable storage device per some embodiments.

Input 1052 includes (1) a stream of encrypted test bit chunks (128-bit chunks in this example), (2) counter values at references 1002 to 1008, which are generated through a set of IDs (not shown) similar to the ones shown at reference 850. The counter values at references 1002 to 1008 apply to AES keys Ek at references 1010 to 1016, and exclusive OR (XOR) operates on the resulting values and corresponding CT blocks (the encrypted text bit chunks) at references 1018 to 1024 and generates plain text bit blocks at references 1026 to 1032.

Referring back to FIG. 9, the plain text bit blocks are routed to data buffer 0 (DB0) and DB1 at references 928 and 930, and the CCSAT decoder 934 further processes the plain text, e.g., loading and execution as discussed relating to FIGS. 1 to 5. For example, the CCSAT decoder 934 may perform the operations of decoder 310 in FIG. 3.

SHA-256 module 912 calculates the SHA-256 digest of the CCSAT sub block hash (CSH) as encrypted (see FIG. 6). The CSH is used by EAU 910 to generate the CSH_Auth_Pass 962 for RSA compare 916 as shown in FIG. 9. SHA-256 module 912 also calculates the hash of each block, which is compared against the content of the CSH by Hash Compare 918, which generates the CCSAT_Hash_Match 964.

In some embodiments, SHA-256 module 912 performs SHA-256 defined in Federal Information Processing Standards Publication (FIPS) Pub 180-4 as defined by the National Institute of Standards and Technology. SHA-256 module 912 consumes 32 bits of data per cycle and has an update throughput of 64B/66 cycles, excluding padding and final processing. Its throughput is slightly faster than 1B per cycle.

EAU 910 may be implemented as a hardware acceleration unit for performing RSA signature verification. EAU 910 performs a specific mathematical operation involving the exponentiation of large numbers (e.g., 2048 bits) with a specific Register Transfer Level (RTL) parameterized exponent value. EAU 910 may include registers for configuration, command, and status, as well as a memory (e.g., RAM) which can be implemented using flops or radio frequencies (RFs). These elements of EAU 910 may be accessed through a simple read/write register interface. EAU 910 may be programmed by writing into the configuration and command registers. In addition, the RSA public key 906 may be written into the memory. The status register is constantly updated by EAU 910 while it executes and can be read out at any time. The status register indicates if EAU 910 is idle, busy (calculation in progress) or done. EAU 910 outputs the 32 bytes of verified hash along with PKCS 1.5 padding. EAU 910 takes about 35,000 cycles to complete its computation in some embodiments.

### Block Group Decryption and Verification

### CSH Verification

The decryption and verification of test patterns/test results may be implemented as shown in the CCSAT decryption flow 900. The decryption and verification are performed at the block group level in some embodiments. The encrypted input of byte stream 901 is the input, and the encrypted byte instream 910 includes the test sequences after encryption in some embodiments as discussed in FIGS. 6 to 8. The data stored in a CCSAT clock crossing First-in-First-out (FIFO) buffer 902, and the data in the buffer (e.g., in 64-byte chunks) at reference 904 are provided for the decryption and verification.

The first bytes of a test sequence belong to the test sequence header (e.g., test sequence header 708), and they are followed by an RSA signature (e.g., the 256-byte RSA signature of block group 620). The RSA signature along with the RSA public key stored in Register Transfer Level (RTL) parameter at reference 906 are the inputs to the EAU 910.

EAU 910 processes the input RSA public key 906 and signature 908 and computes a 256-byte output in some embodiments. The first 32 bytes include the decrypted hash of hash, and the rest are padding, per PKCSv1.5 padding. The EAU 910 outputs bytes of verified hash along with PKCS1.5 padding. In some embodiments, EAU 910 takes about 35,000 cycles to complete its computation.

The next encrypted data of the test sequence to be processed is the 128 hashes that comprises CSH. The CSH is stored in a hash buffer 914. An CCSAT counter calculates an expected block group ID. To prevent a block group swapping attacks, the block group ID is attached to the CSH data so that the expected block group ID may be used to compare to the embedded block group ID during the encryption process (e.g., see the hash at reference 608).

The CSH data with the attachment are fed to SHA-256 module 912 to compute the hash on hash. The hash on hash computed by SHA-256 module 912 is a 32-byte hash of size. This is compared with output of EAU 910 at reference 918 as discussed above. If these two outputs match, then we have successfully verified the CSH data. The SHA-256 processes one byte per cycle in some embodiments and this verification process for the entire CSH takes 4K cycles.

### Block Decryption

Following the CSH (which is in block 0 of the block group structure 772 in some embodiments), the rest of the blocks in the block group are processed. Block processing involves two steps, performed concurrently in some embodiments: decryption and verification. The cypher text (CT) of each block is first decrypted by AES-CTR 926 to get the plain text blocks as described previously.

Two ping pong buffers, DB0 and DB1 each of size 4 Kbytes at references 928 and 930 are implemented in some embodiments. To start with, the first incoming block, after decryption, is stored in DB0 928. This data is not processed until it is authenticated at reference 965 through SHA-256 912 and EAU 910. Once authentication is complete, the block in DB0 is consumed by CCSAT decoder 934 for further processing. While the block in DB0 is being processed by CCSAT decoder 934, a new incoming block is first decrypted, stored in DB1 and verified. The processing of DB1 by CCSAT decoder 934 is delayed till DB0 is processed. Block processing continues by filling in DB0 while DB1 is being consumed by CCSAT decoder 934. The alternating interaction of ping pong buffers with CCSAT decoder 934 allows the blocks to be processed more efficiently.

### Block Verification

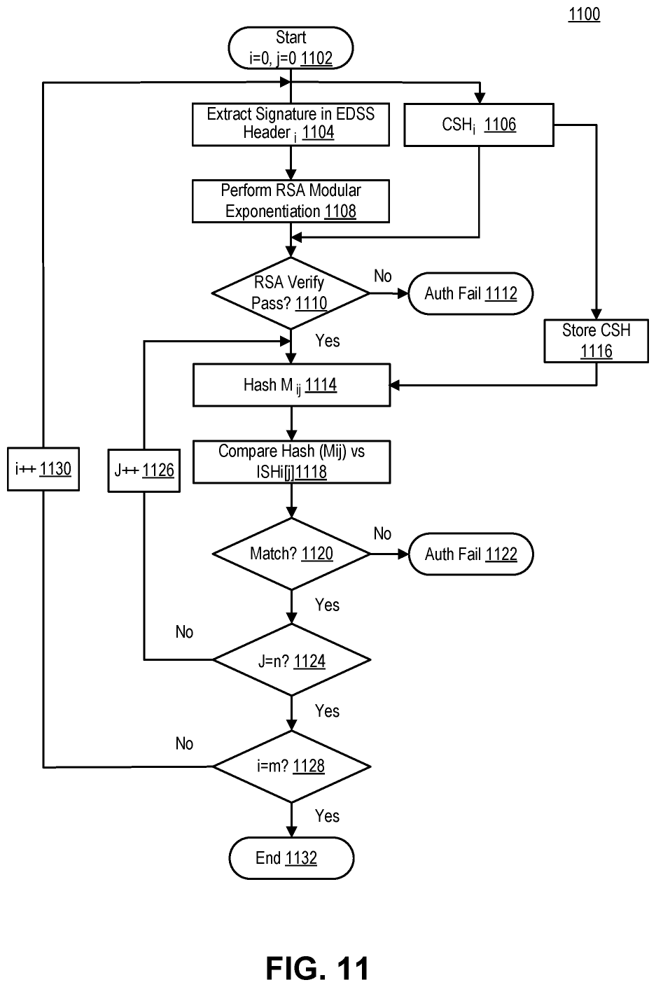

FIG. 11 illustrates block verification of a test sequence per some embodiments. When the cypher text (CT) blocks are forwarded to AES-CTR module 926, it is also forwarded to SHA-256 module 912 for authentication. SHA-256 module 912 starts computing the 32-byte hash for the data it receives. Once SHA-256 module 912 completes processing the 4 KB of data belonging to a block, the computed hash is compared at reference 918 with the 32-byte true hash for this block that is stored in the hash buffer 914. If the true hash matches the computed hash, then the current block is authenticated and released for processing by CCSAT decoder 934. The authentication of a block by SHA-256 module 912 takes 4K clock cycles in some embodiments.

As shown in the figure, the block verification runs through a set of block groups, 0 to i, and each block within a block group having a hash, Mij. The hash is compared with the expected CCSAT sub block hash (CSH). Process 1100 includes two loops, and operates on the ESA signature at reference 1104, and performs RSA modular exponentiation at reference 1108. If the RSA verification fails, the process stops at reference 1112. Otherwise, the process continues at reference 1114 to compute the hash, Mij. The computed hash is compared with the true hash at reference 1120, which is obtained from the stored CSH at reference 1116. If a match is found, the process continues to the next block at reference 1124, the process fails otherwise at reference 1122. The process finishes successfully with all block groups within a test sequence if no authentication failure is encountered leading to either reference 1112 or 1122.

While the decryption of encrypted test patterns is discussed herein as an example, encrypted test results may be decrypted in similar operations as shown in FIGS. 9 to 11. Through the encryption and decryption of test patterns, test ID, and/or test results, unauthorized access to the test patterns and test results may be prevented, even if an unauthorized party has gained access to the portable storage device and/or the target system for which test patterns are to be run to detect hardware defects. The encrypted content is not understandable without decryption, and an authentication failure during decryption would cause exit of the authentication process and prevent tampering of the encrypted content used in the hardware defect detection.

### Encryption Enhancement

A test ID is used in AES encryption in some embodiments, as shown in FIG. 8. The test ID of a test pattern maps to an ID of the target system on which the test pattern is supposed to execute. When the test ID of the test pattern does not match the ID of the target system, the authentication fails, and the test pattern is not executed. The test ID is thus used to authenticate the test pattern prior to executing the test pattern on the target system. The security of a test ID to be mapped to a test pattern may be further enhanced by generating a new nonce based on a test ID for encryption.

FIG. 12 illustrates security enhance of an AES nonce per some embodiments. The input is a test ID 1232, a string 1234, and a nonce 1236 that is generated by a Deterministic Random Number Generator (DRNG) 1214. The test ID may be the test ID 892, and the string 1234 may include block group ID 854 and/or block ID 856. The three input values are hashed at reference 1240. The value may be truncated to a fixed length at reference 1242. The resulting pseudonym 1256, the generated nonce 1254, and the current time obtained from a Perfect Randomness Transfer and Compression (PRTC) module 1220 as the base time 1252. The three data values are used to generate the nonce 1250 for AES encryption. In some embodiment, the generation of the nonce 1250 is to hash the three data values and the resulting hash is nonce 1250.

The nonce enhancement with test ID information embedded provides further security of the encryption to ensure that only mapping target systems may execute the test patterns, and the mapping is verified through a test ID match.

### Operations in Some Embodiments

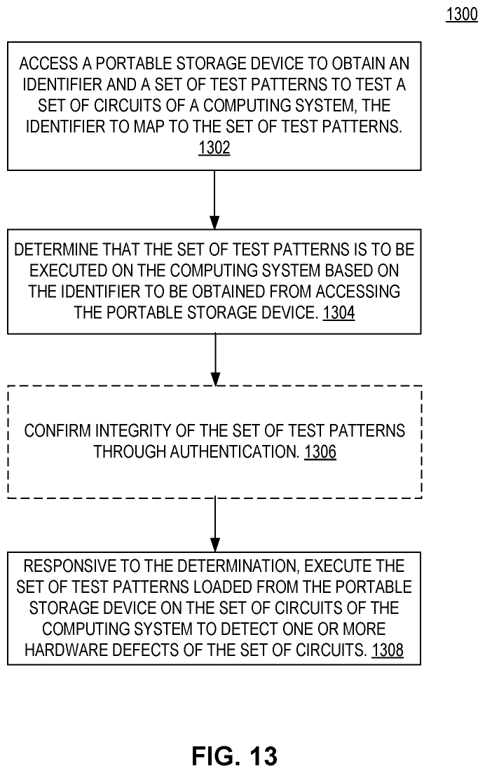

FIG. 13 illustrates a flow diagram to detect hardware defects using a portable storage device per some embodiments. The operations in method 1300 are performed by CCSAT module 160 of a target system discussed herein.

At reference 1302, a portable storage device is accessed to obtain an identifier (ID) and a set of test patterns to test the set of circuits, the identifier to map to the set of test patterns. The ID is a test ID (e.g., one of test IDs 192 or test ID 892) in some embodiments.

At reference 1304, it is determined that the set of test patterns is to be executed on the computing system based on the identifier to be obtained from accessing the portable storage device.

At reference 1308, responsive to the determination, the set of test patterns loaded from the portable storage device is executed on the set of circuits of the computing system to detect one or more hardware defects of the set of circuits.

In some embodiments, determining that the set of test patterns is to be executed on the computing system comprises a determination that the identifier to be obtained from accessing the portable storage device matches to an identifier corresponding to the computing system.

In some embodiments, the identifier corresponding to the computing system is a part identifier (PID), a die identifier, or silicon stepping ID. The Identifier is test ID in some embodiments.

In some embodiments, the set of test patterns is to target structural defects of the set of circuits, including defects regarding layout of transistors within the computing system, and regarding connections between the transistors. Structural testing discussed herein above includes the test patterns in some embodiments.

In some embodiments, the detection of the one or more hardware defects is to be performed through a boot up process of the computing system. The process is discussed in further detail herein, for example, in the “Detection & Loading” section.

In some embodiments, the portable storage device is a Universal Serial Bus (USB) device, wherein the USB device is a USB Type-C device to operate at a power delivery (PD) alternate mode, and wherein the detection of the one or more hardware defects is to be initiated through a command. The process is discussed in further detail herein, for example, in the “USB—C Based Loading” section. Alternatively, the USB Type-C device operates at the debug accessory mode.

In some embodiments, the portable storage device is a Universal Serial Bus (USB) device, wherein the set of test patterns is identified with a USB class identifier, and wherein a USB driver or an operating system (OS) of the computing system is to coordinate operations of the detection of the one or more hardware defects based on the USB class identifier. The process is discussed in further detail herein, for example, in the “OS/USB Driver Based Loading” section herein above.

In some embodiments, the set of test patterns is encrypted prior to being stored in the portable storage device, and the method further comprises, confirming integrity of the set of test patterns through authentication prior to executing the set of test patterns at reference 1306. The encryption is discussed in further detail herein above relating to FIGS. 4, and 6 to 12.

In some embodiments, the set of test patterns is encrypted with an Advanced Encryption Standard (AES) encryption, where integrity of the set of test patterns is confirmed decryption of the encrypted set of test patterns. The AES encryption/decryption is explained in further detail herein, e.g., paragraphs relating to FIGS. 6 to 12.

In some embodiments, the AES encryption to encrypt the set of test patterns is to operate at an AES counter mode, wherein a plurality of blocks is to be generated from the set of test patterns in the AES counter mode, and a block within the plurality of blocks is to include a counter, and wherein the counter identifies the computing system.

In some embodiments, each of the plurality of blocks is encrypted through a first Secure Hash Algorithm (SHA) encryption to generate a first plurality of bytes.

In some embodiments, the first plurality of bytes is encrypted through a second SHA encryption to generate a second plurality of bytes.

In some embodiments, the second plurality of bytes is to be padded through a Public Key Cryptography Standards (PKCS) padding to generate a third plurality of bytes, wherein the third plurality of bytes is to be signed with an RSA (Rivest-Shamir-Adleman) private key to generate a signature.

In some embodiments, the signature is saved as a header to be stored along with the third plurality of the bytes. For example, the header is shown in FIGS. 6 and 7.

### Example Systems

FIG. 14 illustrates an example computing system. Multiprocessor system 1400 is an interfaced system and includes a plurality of processors or cores including a first processor 1470 and a second processor 1480 coupled via an interface 1450 such as a point-to-point (P-P) interconnect, a fabric, and/or bus. In some examples, the first processor 1470 and the second processor 1480 are homogeneous. In some examples, the first processor 1470 and the second processor 1480 are heterogenous. Though the example system 1400 is shown to have two processors, the system may have three or more processors, or may be a single processor system. In some examples, the computing system is a system on a chip (SoC).

Processors 1470 and 1480 are shown including integrated memory controller (IMC) circuitry 1472 and 1482, respectively. Processor 1470 also includes interface circuits 1476 and 1478; similarly, second processor 1480 includes interface circuits 1486 and 1488. Processors 1470, 1480 may exchange information via the interface 1450 using interface circuits 1478, 1488. IMCs 1472 and 1482 couple the processors 1470, 1480 to respective memories, namely a memory 1432 and a memory 1434, which may be portions of main memory locally attached to the respective processors.

Processors 1470, 1480 may each exchange information with a network interface (NW I/F) 1490 via individual interfaces 1452, 1454 using interface circuits 1476, 1494, 1486, 1498. The network interface 1490 (e.g., one or more of an interconnect, bus, and/or fabric, and in some examples is a chipset) may optionally exchange information with a coprocessor 1438 via an interface circuit 1492. In some examples, the coprocessor 1438 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 1470, 1480 or outside of both processors, yet connected with the processors via an interface such as P-P interconnect, such that either or both processors' local cache information may be stored in the shared cache if a processor is placed into a low power mode.

Network interface 1490 may be coupled to a first interface 1416 via interface circuit 1496. In some examples, first interface 1416 may be an interface such as a Peripheral Component Interconnect (PCI) interconnect, a PCI Express interconnect or another I/O interconnect. In some examples, first interface 1416 is coupled to a power control unit (PCU) 1417, which may include circuitry, software, and/or firmware to perform power management operations with regard to the processors 1470, 1480 and/or co-processor 1438. PCU 1417 provides control information to a voltage regulator (not shown) to cause the voltage regulator to generate the appropriate regulated voltage. PCU 1417 also provides control information to control the operating voltage generated. In various examples, PCU 1417 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 1417 is illustrated as being present as logic separate from the processor 1470 and/or processor 1480. In other cases, PCU 1417 may execute on a given one or more of cores (not shown) of processor 1470 or 1480. In some cases, PCU 1417 may be implemented as a microcontroller (dedicated or general-purpose) or other control logic configured to execute its own dedicated power management code, sometimes referred to as P-code. In yet other examples, power management operations to be performed by PCU 1417 may be implemented externally to a processor, such as by way of a separate power management integrated circuit (PMIC) or another component external to the processor. In yet other examples, power management operations to be performed by PCU 1417 may be implemented within BIOS or other system software.

Various I/O devices 1414 may be coupled to first interface 1416, along with a bus bridge 1418 which couples first interface 1416 to a second interface 1420. In some examples, one or more additional processor(s) 1415, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 1416. In some examples, second interface 1420 may be a low pin count (LPC) interface. Various devices may be coupled to second interface 1420 including, for example, a keyboard and/or mouse 1422, communication devices 1427 and storage circuitry 1428. Storage circuitry 1428 may be one or more non-transitory machine-readable storage media as described below, such as a disk drive or other mass storage device which may include instructions/code and data 1430 and may implement the storage 'ISAB03 in some examples. Further, an audio I/O 1424 may be coupled to second interface 1420. Note that other architectures than the point-to-point architecture described above are possible. For example, instead of the point-to-point architecture, a system such as multiprocessor system 1400 may implement a multi-drop interface or other such architecture.

Example Core Architectures, Processors, and Computer Architectures.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

FIG. 15 illustrates a block diagram of an example processor and/or SoC 1500 that may have one or more cores and an integrated memory controller. The solid lined boxes illustrate a processor 1500 with a single core 1502(A), system agent unit circuitry 1510, and a set of one or more interface controller unit(s) circuitry 1516, while the optional addition of the dashed lined boxes illustrates an alternative processor 1500 with multiple cores 1502(A)-(N), a set of one or more integrated memory controller unit(s) circuitry 1514 in the system agent unit circuitry 1510, and special purpose logic 1508, as well as a set of one or more interface controller units circuitry 1516. Note that the processor 1500 may be one of the processors 1470 or 1480, or co-processor 1438 or 1415 of FIG. 14.

Thus, different implementations of the processor 1500 may include: 1) a CPU with the special purpose logic 1508 being integrated graphics and/or scientific (throughput) logic (which may include one or more cores, not shown), and the cores 1502(A)-(N) being one or more general purpose cores (e.g., general purpose in-order cores, general purpose out-of-order cores, or a combination of the two); 2) a coprocessor with the cores 1502(A)-(N) being a large number of special purpose cores intended primarily for graphics and/or scientific (throughput); and 3) a coprocessor with the cores 1502(A)-(N) being a large number of general purpose in-order cores. Thus, the processor 1500 may be a general-purpose processor, coprocessor or special-purpose processor, such as, for example, a network or communication processor, compression engine, graphics processor, GPGPU (general purpose graphics processing unit), a high throughput many integrated core (MIC) coprocessor (including 30 or more cores), embedded processor, or the like. The processor may be implemented on one or more chips. The processor 1500 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 1504(A)-(N) within the cores 1502(A)-(N), a set of one or more shared cache unit(s) circuitry 1506, and external memory (not shown) coupled to the set of integrated memory controller unit(s) circuitry 1514. The set of one or more shared cache unit(s) circuitry 1506 may include one or more mid-level caches, such as level 2 (L2), level 3 (L3), level 4 (L4), or other levels of cache, such as a last level cache (LLC), and/or combinations thereof. While in some examples interface network circuitry 1512 (e.g., a ring interconnect) interfaces the special purpose logic 1508 (e.g., integrated graphics logic), the set of shared cache unit(s) circuitry 1506, and the system agent unit circuitry 1510, alternative examples use any number of well-known techniques for interfacing such units. In some examples, coherency is maintained between one or more of the shared cache unit(s) circuitry 1506 and cores 1502(A)-(N). In some examples, interface controller units circuitry 1516 couple the cores 1502 to one or more other devices 1518 such as one or more I/O devices, storage, one or more communication devices (e.g., wireless networking, wired networking, etc.), etc.

In some examples, one or more of the cores 1502(A)-(N) are capable of multi-threading. The system agent unit circuitry 1510 includes those components coordinating and operating cores 1502(A)-(N). The system agent unit circuitry 1510 may include, for example, power control unit (PCU) circuitry and/or display unit circuitry (not shown). The PCU may be or may include logic and components needed for regulating the power state of the cores 1502(A)-(N) and/or the special purpose logic 1508 (e.g., integrated graphics logic). The display unit circuitry is for driving one or more externally connected displays.

The cores 1502(A)-(N) may be homogenous in terms of instruction set architecture (ISA). Alternatively, the cores 1502(A)-(N) may be heterogeneous in terms of ISA; that is, a subset of the cores 1502(A)-(N) may be capable of executing an ISA, while other cores may be capable of executing only a subset of that ISA or another ISA.

FIG. 16 is a block diagram illustrating a computing system 1600 configured to implement one or more aspects of the examples described herein. The computing system 1600 includes a processing subsystem 1601 having one or more processor(s) 1602 and a system memory 1604 communicating via an interconnection path that may include a memory hub 1605. The memory hub 1605 may be a separate component within a chipset component or may be integrated within the one or more processor(s) 1602. The memory hub 1605 couples with an I/O subsystem 1611 via a communication link 1606. The I/O subsystem 1611 includes an I/O hub 1607 that can enable the computing system 1600 to receive input from one or more input device(s) 1608. Additionally, the I/O hub 1607 can enable a display controller, which may be included in the one or more processor(s) 1602, to provide outputs to one or more display device(s) 1610A. In some examples the one or more display device(s) 1610A coupled with the I/O hub 1607 can include a local, internal, or embedded display device.

The processing subsystem 1601, for example, includes one or more parallel processor(s) 1612 coupled to memory hub 1605 via a bus or other communication link 1613. The communication link 1613 may be one of any number of standards-based communication link technologies or protocols, such as, but not limited to PCI Express, or may be a vendor specific communications interface or communications fabric. The one or more parallel processor(s) 1612 may form a computationally focused parallel or vector processing system that can include a large number of processing cores and/or processing clusters, such as a many integrated core (MIC) processor. For example, the one or more parallel processor(s) 1612 form a graphics processing subsystem that can output pixels to one of the one or more display device(s) 1610A coupled via the I/O hub 1607. The one or more parallel processor(s) 1612 can also include a display controller and display interface (not shown) to enable a direct connection to one or more display device(s) 1610B.

Within the I/O subsystem 1611, a system storage unit 1614 can connect to the I/O hub 1607 to provide a storage mechanism for the computing system 1600. An I/O switch 1616 can be used to provide an interface mechanism to enable connections between the I/O hub 1607 and other components, such as a network adapter 1618 and/or wireless network adapter 1619 that may be integrated into the platform, and various other devices that can be added via one or more add-in device(s) 1620. The add-in device(s) 1620 may also include, for example, one or more external graphics processor devices, graphics cards, and/or compute accelerators. The network adapter 1618 can be an Ethernet adapter or another wired network adapter. The wireless network adapter 1619 can include one or more of a Wi-Fi, Bluetooth, near field communication (NFC), or other network device that includes one or more wireless radios.

The computing system 1600 can include other components not explicitly shown, including USB or other port connections, optical storage drives, video capture devices, and the like, which may also be connected to the I/O hub 1607. Communication paths interconnecting the various components in FIG. 16 may be implemented using any suitable protocols, such as PCI (Peripheral Component Interconnect) based protocols (e.g., PCI-Express), or any other bus or point-to-point communication interfaces and/or protocol(s), such as the NVLink high-speed interconnect, Compute Express LinkTM (CXLTM) (e.g., CXL.mem), Infinity Fabric (IF), Ethernet (IEEE 802.3), remote direct memory access (RDMA), InfiniBand, Internet Wide Area RDMA Protocol (iWARP), Transmission Control Protocol (TCP), User Datagram Protocol (UDP), quick UDP Internet Connections (QUIC), RDMA over Converged Ethernet (RoCE), Intel QuickPath Interconnect (QPI), Intel Ultra Path Interconnect (UPI), Intel On-Chip System Fabric (IOSF), Omnipath, HyperTransport, Advanced Microcontroller Bus Architecture (AMBA) interconnect, OpenCAPI, Gen-Z, Cache Coherent Interconnect for Accelerators (CCIX), 3GPP Long Term Evolution (LTE) (4G), 3GPP 5G, and variations thereof, or wired or wireless interconnect protocols known in the art. In some examples, data can be copied or stored to virtualized storage nodes using a protocol such as non-volatile memory express (NVMe) over Fabrics (NVMe-oF) or NVMe.

The one or more parallel processor(s) 1612 may incorporate circuitry optimized for graphics and video processing, including, for example, video output circuitry, and constitutes a graphics processing unit (GPU). Alternatively or additionally, the one or more parallel processor(s) 1612 can incorporate circuitry optimized for general purpose processing, while preserving the underlying computational architecture, described in greater detail herein. Components of the computing system 1600 may be integrated with one or more other system elements on a single integrated circuit. For example, the one or more parallel processor(s) 1612, memory hub 1605, processor(s) 1602, and I/O hub 1607 can be integrated into a system on chip (SoC) integrated circuit. Alternatively, the components of the computing system 1600 can be integrated into a single package to form a system in package (SIP) configuration. In some examples at least a portion of the components of the computing system 1600 can be integrated into a multi-chip module (MCM), which can be interconnected with other multi-chip modules into a modular computing system.

It will be appreciated that the computing system 1600 shown herein is illustrative and that variations and modifications are possible. The connection topology, including the number and arrangement of bridges, the number of processor(s) 1602, and the number of parallel processor(s) 1612, may be modified as desired. For instance, system memory 1604 can be connected to the processor(s) 1602 directly rather than through a bridge, while other devices communicate with system memory 1604 via the memory hub 1605 and the processor(s) 1602. In other alternative topologies, the parallel processor(s) 1612 are connected to the I/O hub 1607 or directly to one of the one or more processor(s) 1602, rather than to the memory hub 1605. In other examples, the I/O hub 1607 and memory hub 1605 may be integrated into a single chip. It is also possible that two or more sets of processor(s) 1602 are attached via multiple sockets, which can couple with two or more instances of the parallel processor(s) 1612.

Some of the particular components shown herein are optional and may not be included in all implementations of the computing system 1600. For example, any number of add-in cards or peripherals may be supported, or some components may be eliminated. Furthermore, some architectures may use different terminology for components similar to those illustrated in FIG. 16. For example, the memory hub 1605 may be referred to as a Northbridge in some architectures, while the I/O hub 1607 may be referred to as a Southbridge.

FIG. 17A illustrates examples of a parallel processor 1700. The parallel processor 1700 may be a GPU, GPGPU or the like as described herein. The various components of the parallel processor 1700 may be implemented using one or more integrated circuit devices, such as programmable processors, application specific integrated circuits (ASICs), or field programmable gate arrays (FPGA). The illustrated parallel processor 1700 may be one or more of the parallel processor(s) 1612 shown in FIG. 16.

The parallel processor 1700 includes a parallel processing unit 1702. The parallel processing unit includes an I/O unit 1704 that enables communication with other devices, including other instances of the parallel processing unit 1702. The I/O unit 1704 may be directly connected to other devices. For instance, the I/O unit 1704 connects with other devices via the use of a hub or switch interface, such as memory hub 1605. The connections between the memory hub 1605 and the I/O unit 1704 form a communication link 1613. Within the parallel processing unit 1702, the I/O unit 1704 connects with a host interface 1706 and a memory crossbar 1716, where the host interface 1706 receives commands directed to performing processing operations and the memory crossbar 1716 receives commands directed to performing memory operations.

When the host interface 1706 receives a command buffer via the I/O unit 1704, the host interface 1706 can direct work operations to perform those commands to a front end 1708. In some examples the front end 1708 couples with a scheduler 1710, which is configured to distribute commands or other work items to a processing cluster array 1712. The scheduler 1710 ensures that the processing cluster array 1712 is properly configured and in a valid state before tasks are distributed to the processing clusters of the processing cluster array 1712. The scheduler 1710 may be implemented via firmware logic executing on a microcontroller. The microcontroller implemented scheduler 1710 is configurable to perform complex scheduling and work distribution operations at coarse and fine granularity, enabling rapid preemption and context switching of threads executing on the processing cluster array 1712. Preferably, the host software can prove workloads for scheduling on the processing cluster array 1712 via one of multiple graphics processing doorbells. In other examples, polling for new workloads or interrupts can be used to identify or indicate availability of work to perform. The workloads can then be automatically distributed across the processing cluster array 1712 by the scheduler 1710 logic within the scheduler microcontroller.

The processing cluster array 1712 can include up to “N” processing clusters (e.g., cluster 1714A, cluster 1714B, through cluster 1714N). Each cluster 1714A-1714N of the processing cluster array 1712 can execute a large number of concurrent threads. The scheduler 1710 can allocate work to the clusters 1714A-1714N of the processing cluster array 1712 using various scheduling and/or work distribution algorithms, which may vary depending on the workload arising for each type of program or computation. The scheduling can be handled dynamically by the scheduler 1710 or can be assisted in part by compiler logic during compilation of program logic configured for execution by the processing cluster array 1712. Optionally, different clusters 1714A-1714N of the processing cluster array 1712 can be allocated for processing different types of programs or for performing different types of computations.

The processing cluster array 1712 can be configured to perform various types of parallel processing operations. For example, the processing cluster array 1712 is configured to perform general-purpose parallel compute operations. For example, the processing cluster array 1712 can include logic to execute processing tasks including filtering of video and/or audio data, performing modeling operations, including physics operations, and performing data transformations.

The processing cluster array 1712 is configured to perform parallel graphics processing operations. In such examples in which the parallel processor 1700 is configured to perform graphics processing operations, the processing cluster array 1712 can include additional logic to support the execution of such graphics processing operations, including, but not limited to texture sampling logic to perform texture operations, as well as tessellation logic and other vertex processing logic. Additionally, the processing cluster array 1712 can be configured to execute graphics processing related shader programs such as, but not limited to vertex shaders, tessellation shaders, geometry shaders, and pixel shaders. The parallel processing unit 1702 can transfer data from system memory via the I/O unit 1704 for processing. During processing the transferred data can be stored to on-chip memory (e.g., parallel processor memory 1722) during processing, then written back to system memory.

In examples in which the parallel processing unit 1702 is used to perform graphics processing, the scheduler 1710 may be configured to divide the processing workload into approximately equal sized tasks, to better enable distribution of the graphics processing operations to multiple clusters 1714A-1714N of the processing cluster array 1712. In some of these examples, portions of the processing cluster array 1712 can be configured to perform different types of processing. For example, a first portion may be configured to perform vertex shading and topology generation, a second portion may be configured to perform tessellation and geometry shading, and a third portion may be configured to perform pixel shading or other screen space operations, to produce a rendered image for display. Intermediate data produced by one or more of the clusters 1714A-1714N may be stored in buffers to allow the intermediate data to be transmitted between clusters 1714A-1714N for further processing.

During operation, the processing cluster array 1712 can receive processing tasks to be executed via the scheduler 1710, which receives commands defining processing tasks from front end 1708. For graphics processing operations, processing tasks can include indices of data to be processed, e.g., surface (patch) data, primitive data, vertex data, and/or pixel data, as well as state parameters and commands defining how the data is to be processed (e.g., what program is to be executed). The scheduler 1710 may be configured to fetch the indices corresponding to the tasks or may receive the indices from the front end 1708. The front end 1708 can be configured to ensure the processing cluster array 1712 is configured to a valid state before the workload specified by incoming command buffers (e.g., batch-buffers, push buffers, etc.) is initiated.

Each of the one or more instances of the parallel processing unit 1702 can couple with parallel processor memory 1722. The parallel processor memory 1722 can be accessed via the memory crossbar 1716, which can receive memory requests from the processing cluster array 1712 as well as the I/O unit 1704. The memory crossbar 1716 can access the parallel processor memory 1722 via a memory interface 1718. The memory interface 1718 can include multiple partition units (e.g., partition unit 1720A, partition unit 1720B, through partition unit 1720N) that can each couple to a portion (e.g., memory unit) of parallel processor memory 1722. The number of partition units 1720A-172ON may be configured to be equal to the number of memory units, such that a first partition unit 1720A has a corresponding first memory unit 1724A, a second partition unit 1720B has a corresponding second memory unit 1724B, and an Nth partition unit 1720N has a corresponding Nth memory unit 1724N. In other examples, the number of partition units 1720A-1720N may not be equal to the number of memory devices.

The memory units 1724A-1724N can include various types of memory devices, including dynamic random-access memory (DRAM) or graphics random access memory, such as synchronous graphics random access memory (SGRAM), including graphics double data rate (GDDR) memory. Optionally, the memory units 1724A-1724N may also include 3D stacked memory, including but not limited to high bandwidth memory (HBM). Persons skilled in the art will appreciate that the specific implementation of the memory units 1724A-1724N can vary and can be selected from one of various conventional designs. Render targets, such as frame buffers or texture maps may be stored across the memory units 1724A-1724N, allowing partition units 1720A-1720N to write portions of each render target in parallel to efficiently use the available bandwidth of parallel processor memory 1722. In some examples, a local instance of the parallel processor memory 1722 may be excluded in favor of a unified memory design that utilizes system memory in conjunction with local cache memory.

Optionally, any one of the clusters 1714A-1714N of the processing cluster array 1712 has the ability to process data that will be written to any of the memory units 1724A-1724N within parallel processor memory 1722. The memory crossbar 1716 can be configured to transfer the output of each cluster 1714A-1714N to any partition unit 1720A-1720N or to another cluster 1714A-1714N, which can perform additional processing operations on the output. Each cluster 1714A-1714N can communicate with the memory interface 1718 through the memory crossbar 1716 to read from or write to various external memory devices. In one of the examples with the memory crossbar 1716 the memory crossbar 1716 has a connection to the memory interface 1718 to communicate with the I/O unit 1704, as well as a connection to a local instance of the parallel processor memory 1722, enabling the processing units within the different processing clusters 1714A-1714N to communicate with system memory or other memory that is not local to the parallel processing unit 1702. Generally, the memory crossbar 1716 may, for example, be able to use virtual channels to separate traffic streams between the clusters 1714A-1714N and the partition units 1720A-1720N.

While a single instance of the parallel processing unit 1702 is illustrated within the parallel processor 1700, any number of instances of the parallel processing unit 1702 can be included. For example, multiple instances of the parallel processing unit 1702 can be provided on a single add-in card, or multiple add-in cards can be interconnected. For example, the parallel processor 1700 can be an add-in device, such as add-in device 1620 of FIG. 16, which may be a graphics card such as a discrete graphics card that includes one or more GPUs, one or more memory devices, and device-to-device or network or fabric interfaces. The different instances of the parallel processing unit 1702 can be configured to inter-operate even if the different instances have different numbers of processing cores, different amounts of local parallel processor memory, and/or other configuration differences. Optionally, some instances of the parallel processing unit 1702 can include higher precision floating point units relative to other instances. Systems incorporating one or more instances of the parallel processing unit 1702 or the parallel processor 1700 can be implemented in a variety of configurations and form factors, including but not limited to desktop, laptop, or handheld personal computers, servers, workstations, game consoles, and/or embedded systems. An orchestrator can form composite nodes for workload performance using one or more of: disaggregated processor resources, cache resources, memory resources, storage resources, and networking resources.

In some examples, the parallel processing unit 1702 can be partitioned into multiple instances. Those multiple instances can be configured to execute workloads associated with different clients in an isolated manner, enabling a pre-determined quality of service to be provided for each client. For example, each cluster 1714A-1714N can be compartmentalized and isolated from other clusters, allowing the processing cluster array 1712 to be divided into multiple compute partitions or instances. In such configuration, workloads that execute on an isolated partition are protected from faults or errors associated with a different workload that executes on a different partition. The partition units 1720A-1720N can be configured to enable a dedicated and/or isolated path to memory for the clusters 1714A-1714N associated with the respective compute partitions. This datapath isolation enables the compute resources within a partition can communicate with one or more assigned memory units 1724A-1724N without being subjected to inference by the activities of other partitions.

FIG. 17B is a block diagram of a partition unit 1720. The partition unit 1720 may be an instance of one of the partition units 1720A-1720N of FIG. 17A. As illustrated, the partition unit 1720 includes an L2 cache 1721, a frame buffer interface 1725, and a ROP 1726 (raster operations unit). The L2 cache 1721 is a read/write cache that is configured to perform load and store operations received from the memory crossbar 1716 and ROP 1726. Read misses and urgent write-back requests are output by L2 cache 1721 to frame buffer interface 1725 for processing. Updates can also be sent to the frame buffer via the frame buffer interface 1725 for processing. In some examples the frame buffer interface 1725 interfaces with one of the memory units in parallel processor memory, such as the memory units 1724A-1724N of FIG. 17A (e.g., within parallel processor memory 1722). The partition unit 1720 may additionally or alternatively also interface with one of the memory units in parallel processor memory via a memory controller (not shown).

In graphics applications, the ROP 1726 is a processing unit that performs raster operations such as stencil, z test, blending, and the like. The ROP 1726 then outputs processed graphics data that is stored in graphics memory. In some examples the ROP 1726 includes or couples with a CODEC 1727 that includes compression logic to compress depth or color data that is written to memory or the L2 cache 1721 and decompress depth or color data that is read from memory or the L2 cache 1721. The compression logic can be lossless compression logic that makes use of one or more of multiple compression algorithms. The type of compression that is performed by the CODEC 1727 can vary based on the statistical characteristics of the data to be compressed. For example, in some examples, delta color compression is performed on depth and color data on a per-tile basis. In some examples the CODEC 1727 includes compression and decompression logic that can compress and decompress compute data associated with machine learning operations. The CODEC 1727 can, for example, compress sparse matrix data for sparse machine learning operations. The CODEC 1727 can also compress sparse matrix data that is encoded in a sparse matrix format (e.g., coordinate list encoding (COO), compressed sparse row (CSR), compress sparse column (CSC), etc.) to generate compressed and encoded sparse matrix data. The compressed and encoded sparse matrix data can be decompressed and/or decoded before being processed by processing elements or the processing elements can be configured to consume compressed, encoded, or compressed and encoded data for processing.

The ROP 1726 may be included within each processing cluster (e.g., cluster 1714A-1714N of FIG. 17A) instead of within the partition unit 1720. In such example, read and write requests for pixel data are transmitted over the memory crossbar 1716 instead of pixel fragment data. The processed graphics data may be displayed on a display device, such as one of the one or more display device(s) 1610A-1610B of FIG. 16, routed for further processing by the processor(s) 1602, or routed for further processing by one of the processing entities within the parallel processor 1700 of FIG. 17A.

FIG. 17C is a block diagram of a processing cluster 1714 within a parallel processing unit. For example, the processing cluster is an instance of one of the processing clusters 1714A-1714N of FIG. 17A. The processing cluster 1714 can be configured to execute many threads in parallel, where the term “thread” refers to an instance of a particular program executing on a particular set of input data. Optionally, single-instruction, multiple-data (SIMD) instruction issue techniques may be used to support parallel execution of a large number of threads without providing multiple independent instruction units. Alternatively, single-instruction, multiple-thread (SIMT) techniques may be used to support parallel execution of a large number of generally synchronized threads, using a common instruction unit configured to issue instructions to a set of processing engines within each one of the processing clusters. Unlike a SIMD execution regime, where all processing engines typically execute identical instructions, SIMT execution allows different threads to more readily follow divergent execution paths through a given thread program. Persons skilled in the art will understand that a SIMD processing regime represents a functional subset of a SIMT processing regime.

Operation of the processing cluster 1714 can be controlled via a pipeline manager 1732 that distributes processing tasks to SIMT parallel processors. The pipeline manager 1732 receives instructions from the scheduler 1710 of FIG. 17A and manages execution of those instructions via a graphics multiprocessor 1734 and/or a texture unit 1736. The illustrated graphics multiprocessor 1734 is an exemplary instance of a SIMT parallel processor. However, various types of SIMT parallel processors of differing architectures may be included within the processing cluster 1714. One or more instances of the graphics multiprocessor 1734 can be included within a processing cluster 1714. The graphics multiprocessor 1734 can process data and a data crossbar 1740 can be used to distribute the processed data to one of multiple possible destinations, including other shader units. The pipeline manager 1732 can facilitate the distribution of processed data by specifying destinations for processed data to be distributed via the data crossbar 1740.

Each graphics multiprocessor 1734 within the processing cluster 1714 can include an identical set of functional execution logic (e.g., arithmetic logic units, load-store units, etc.). The functional execution logic can be configured in a pipelined manner in which new instructions can be issued before previous instructions are complete. The functional execution logic supports a variety of operations including integer and floating-point arithmetic, comparison operations, Boolean operations, bit-shifting, and computation of various algebraic functions. The same functional-unit hardware could be leveraged to perform different operations and any combination of functional units may be present.

The instructions transmitted to the processing cluster 1714 constitute a thread. A set of threads executing across the set of parallel processing engines is a thread group. A thread group executes the same program on different input data. Each thread within a thread group can be assigned to a different processing engine within a graphics multiprocessor 1734. A thread group may include fewer threads than the number of processing engines within the graphics multiprocessor 1734. When a thread group includes fewer threads than the number of processing engines, one or more of the processing engines may be idle during cycles in which that thread group is being processed. A thread group may also include more threads than the number of processing engines within the graphics multiprocessor 1734. When the thread group includes more threads than the number of processing engines within the graphics multiprocessor 1734, processing can be performed over consecutive clock cycles. Optionally, multiple thread groups can be executed concurrently on the graphics multiprocessor 1734.

The graphics multiprocessor 1734 may include an internal cache memory to perform load and store operations. Optionally, the graphics multiprocessor 1734 can forego an internal cache and use a cache memory (e.g., level 1 (L1) cache 1748) within the processing cluster 1714. Each graphics multiprocessor 1734 also has access to level 2 (L2) caches within the partition units (e.g., partition units 1720A-1720N of FIG. 17A) that are shared among all processing clusters 1714 and may be used to transfer data between threads. The graphics multiprocessor 1734 may also access off-chip global memory, which can include one or more of local parallel processor memory and/or system memory. Any memory external to the parallel processing unit 1702 may be used as global memory. Embodiments in which the processing cluster 1714 includes multiple instances of the graphics multiprocessor 1734 can share common instructions and data, which may be stored in the L1 cache 1748.

Each processing cluster 1714 may include an MMU 1745 (memory management unit) that is configured to map virtual addresses into physical addresses. In other examples, one or more instances of the MMU 1745 may reside within the memory interface 1718 of FIG. 17A. The MMU 1745 includes a set of page table entries (PTEs) used to map a virtual address to a physical address of a tile and optionally a cache line index. The MMU 1745 may include address translation lookaside buffers (TLB) or caches that may reside within the graphics multiprocessor 1734 or the L1 cache 1748 of processing cluster 1714. The physical address is processed to distribute surface data access locality to allow efficient request interleaving among partition units. The cache line index may be used to determine whether a request for a cache line is a hit or miss.

In graphics and computing applications, a processing cluster 1714 may be configured such that each graphics multiprocessor 1734 is coupled to a texture unit 1736 for performing texture mapping operations, e.g., determining texture sample positions, reading texture data, and filtering the texture data. Texture data is read from an internal texture L1 cache (not shown) or in some examples from the L1 cache within graphics multiprocessor 1734 and is fetched from an L2 cache, local parallel processor memory, or system memory, as needed. Each graphics multiprocessor 1734 outputs processed tasks to the data crossbar 1740 to provide the processed task to another processing cluster 1714 for further processing or to store the processed task in an L2 cache, local parallel processor memory, or system memory via the memory crossbar 1716. A preROP 1742 (pre-raster operations unit) is configured to receive data from graphics multiprocessor 1734, direct data to ROP units, which may be located with partition units as described herein (e.g., partition units 1720A-1720N of FIG. 17A). The preROP 1742 unit can perform optimizations for color blending, organize pixel color data, and perform address translations.

It will be appreciated that the core architecture described herein is illustrative and that variations and modifications are possible. Any number of processing units, e.g., graphics multiprocessor 1734, texture units 1736, preROPs 1742, etc., may be included within a processing cluster 1714. Further, while only one processing cluster 1714 is shown, a parallel processing unit as described herein may include any number of instances of the processing cluster 1714. Optionally, each processing cluster 1714 can be configured to operate independently of other processing clusters 1714 using separate and distinct processing units, L1 caches, L2 caches, etc.

FIG. 17D shows an example of the graphics multiprocessor 1734 in which the graphics multiprocessor 1734 couples with the pipeline manager 1732 of the processing cluster 1714. The graphics multiprocessor 1734 has an execution pipeline including but not limited to an instruction cache 1752, an instruction unit 1754, an address mapping unit 1756, a register file 1758, one or more general purpose graphics processing unit (GPGPU) cores 1762, and one or more load/store units 1766. The GPGPU cores 1762 and load/store units 1766 are coupled with cache memory 1772 and shared memory 1770 via a memory and cache interconnect 1768. The graphics multiprocessor 1734 may additionally include tensor and/or ray-tracing cores 1763 that include hardware logic to accelerate matrix and/or ray-tracing operations.

The instruction cache 1752 may receive a stream of instructions to execute from the pipeline manager 1732. The instructions are cached in the instruction cache 1752 and dispatched for execution by the instruction unit 1754. The instruction unit 1754 can dispatch instructions as thread groups (e.g., warps), with each thread of the thread group assigned to a different execution unit within GPGPU core 1762. An instruction can access any of a local, shared, or global address space by specifying an address within a unified address space. The address mapping unit 1756 can be used to translate addresses in the unified address space into a distinct memory address that can be accessed by the load/store units 1766.

The register file 1758 provides a set of registers for the functional units of the graphics multiprocessor 1734. The register file 1758 provides temporary storage for operands connected to the data paths of the functional units (e.g., GPGPU cores 1762, load/store units 1766) of the graphics multiprocessor 1734. The register file 1758 may be divided between each of the functional units such that each functional unit is allocated a dedicated portion of the register file 1758. For example, the register file 1758 may be divided between the different warps being executed by the graphics multiprocessor 1734.

The GPGPU cores 1762 can each include floating point units (FPUs) and/or integer arithmetic logic units (ALUs) that are used to execute instructions of the graphics multiprocessor 1734. In some implementations, the GPGPU cores 1762 can include hardware logic that may otherwise reside within the tensor and/or ray-tracing cores 1763. The GPGPU cores 1762 can be similar in architecture or can differ in architecture. For example and in some examples, a first portion of the GPGPU cores 1762 include a single precision FPU and an integer ALU while a second portion of the GPGPU cores include a double precision FPU. Optionally, the FPUs can implement the IEEE 754-2008 standard for floating point arithmetic or enable variable precision floating point arithmetic. The graphics multiprocessor 1734 can additionally include one or more fixed function or special function units to perform specific functions such as copy rectangle or pixel blending operations. One or more of the GPGPU cores can also include fixed or special function logic.

The GPGPU cores 1762 may include SIMD logic capable of performing a single instruction on multiple sets of data. Optionally, GPGPU cores 1762 can physically execute SIMD4, SIMD8, and SIMD16 instructions and logically execute SIMD1, SIMD2, and SIMD32 instructions. The SIMD instructions for the GPGPU cores can be generated at compile time by a shader compiler or automatically generated when executing programs written and compiled for single program multiple data (SPMD) or SIMT architectures. Multiple threads of a program configured for the SIMT execution model can be executed via a single SIMD instruction. For example and in some examples, eight SIMT threads that perform the same or similar operations can be executed in parallel via a single SIMD8 logic unit.

The memory and cache interconnect 1768 is an interconnect network that connects each of the functional units of the graphics multiprocessor 1734 to the register file 1758 and to the shared memory 1770. For example, the memory and cache interconnect 1768 is a crossbar interconnect that allows the load/store unit 1766 to implement load and store operations between the shared memory 1770 and the register file 1758. The register file 1758 can operate at the same frequency as the GPGPU cores 1762, thus data transfer between the GPGPU cores 1762 and the register file 1758 is very low latency. The shared memory 1770 can be used to enable communication between threads that execute on the functional units within the graphics multiprocessor 1734. The cache memory 1772 can be used as a data cache for example, to cache texture data communicated between the functional units and the texture unit 1736. The shared memory 1770 can also be used as a program managed cached. The shared memory 1770 and the cache memory 1772 can couple with the data crossbar 1740 to enable communication with other components of the processing cluster. Threads executing on the GPGPU cores 1762 can programmatically store data within the shared memory in addition to the automatically cached data that is stored within the cache memory 1772.

FIGS. 18A-18C illustrate additional graphics multiprocessors, according to examples. FIG. 18A-18B illustrate graphics multiprocessors 1825, 1850, which are related to the graphics multiprocessor 1734 of FIG. 17C and may be used in place of one of those. Therefore, the disclosure of any features in combination with the graphics multiprocessor 1734 herein also discloses a corresponding combination with the graphics multiprocessor(s) 1825, 1850, but is not limited to such. FIG. 18C illustrates a graphics processing unit (GPU) 1880 which includes dedicated sets of graphics processing resources arranged into multi-core groups 1865A-1865N, which correspond to the graphics multiprocessors 1825, 1850. The illustrated graphics multiprocessors 1825, 1850 and the multi-core groups 1865A-1865N can be streaming multiprocessors (SM) capable of simultaneous execution of a large number of execution threads.

The graphics multiprocessor 1825 of FIG. 18A includes multiple additional instances of execution resource units relative to the graphics multiprocessor 1734 of FIG. 17D. For example, the graphics multiprocessor 1825 can include multiple instances of the instruction unit 1832A-1832B, register file 1834A-1834B, and texture unit(s) 1844A-1844B. The graphics multiprocessor 1825 also includes multiple sets of graphics or compute execution units (e.g., GPGPU core 1836A-1836B, tensor core 1837A-1837B, ray-tracing core 1838A-1838B) and multiple sets of load/store units 1840A-1840B. The execution resource units have a common instruction cache 1830, texture and/or data cache memory 1842, and shared memory 1846.

The various components can communicate via an interconnect fabric 1827. The interconnect fabric 1827 may include one or more crossbar switches to enable communication between the various components of the graphics multiprocessor 1825. The interconnect fabric 1827 may be a separate, high-speed network fabric layer upon which each component of the graphics multiprocessor 1825 is stacked. The components of the graphics multiprocessor 1825 communicate with remote components via the interconnect fabric 1827. For example, the cores 1836A-1836B, 1837A-1837B, and 1838A-1838B can each communicate with shared memory 1846 via the interconnect fabric 1827. The interconnect fabric 1827 can arbitrate communication within the graphics multiprocessor 1825 to ensure a fair bandwidth allocation between components.

The graphics multiprocessor 1850 of FIG. 18B includes multiple sets of execution resources 1856A-1856D, where each set of execution resource includes multiple instruction units, register files, GPGPU cores, and load store units, as illustrated in FIG. 17D and FIG. 18A. The execution resources 1856A-1856D can work in concert with texture unit(s) 1860A-1860D for texture operations, while sharing an instruction cache 1854, and shared memory 1853. For example, the execution resources 1856A-1856D can share an instruction cache 1854 and shared memory 1853, as well as multiple instances of a texture and/or data cache memory 1858A-1858B. The various components can communicate via an interconnect fabric 1852 similar to the interconnect fabric 1827 of FIG. 18A.

Persons skilled in the art will understand that the architecture described in FIG. 1, 17A-17D, and 18A-18B are descriptive and not limiting as to the scope of the present examples. Thus, the techniques described herein may be implemented on any properly configured processing unit, including, without limitation, one or more mobile application processors, one or more desktop or server central processing units (CPUs) including multi-core CPUs, one or more parallel processing units, such as the parallel processing unit 1702 of FIG. 17A, as well as one or more graphics processors or special purpose processing units, without departure from the scope of the examples described herein.

The parallel processor or GPGPU as described herein may be communicatively coupled to host/processor cores to accelerate graphics operations, machine-learning operations, pattern analysis operations, and various general-purpose GPU (GPGPU) functions. The GPU may be communicatively coupled to the host processor/cores over a bus or other interconnect (e.g., a high-speed interconnect such as PCIe, NVLink, or other known protocols, standardized protocols, or proprietary protocols). In other examples, the GPU may be integrated on the same package or chip as the cores and communicatively coupled to the cores over an internal processor bus/interconnect (i.e., internal to the package or chip). Regardless of the manner in which the GPU is connected, the processor cores may allocate work to the GPU in the form of sequences of commands/instructions contained in a work descriptor. The GPU then uses dedicated circuitry/logic for efficiently processing these commands/instructions.

FIG. 18C illustrates a graphics processing unit (GPU) 1880 which includes dedicated sets of graphics processing resources arranged into multi-core groups 1865A-1865N. While the details of only a single multi-core group 1865A are provided, it will be appreciated that the other multi-core groups 1865B-1865N may be equipped with the same or similar sets of graphics processing resources. Details described with respect to the multi-core groups 1865A-1865N may also apply to any graphics multiprocessor 1734, 1825, 1850 described herein.

As illustrated, a multi-core group 1865A may include a set of graphics cores 1870, a set of tensor cores 1871, and a set of ray tracing cores 1872. A scheduler/dispatcher 1868 schedules and dispatches the graphics threads for execution on the various cores 1870, 1871, 1872. A set of register files 1869 store operand values used by the cores 1870, 1871, 1872 when executing the graphics threads. These may include, for example, integer registers for storing integer values, floating point registers for storing floating point values, vector registers for storing packed data elements (integer and/or floating-point data elements) and tile registers for storing tensor/matrix values. The tile registers may be implemented as combined sets of vector registers.

One or more combined level 1 (L1) caches and shared memory units 1873 store graphics data such as texture data, vertex data, pixel data, ray data, bounding volume data, etc., locally within each multi-core group 1865A. One or more texture units 1874 can also be used to perform texturing operations, such as texture mapping and sampling. A Level 2 (L2) cache 1875 shared by all or a subset of the multi-core groups 1865A-1865N stores graphics data and/or instructions for multiple concurrent graphics threads. As illustrated, the L2 cache 1875 may be shared across a plurality of multi-core groups 1865A-1865N. One or more memory controllers 1867 couple the GPU 1880 to a memory 1866 which may be a system memory (e.g., DRAM) and/or a dedicated graphics memory (e.g., GDDR6 memory).

Input/output (I/O) circuitry 1863 couples the GPU 1880 to one or more I/O devices 1862 such as digital signal processors (DSPs), network controllers, or user input devices. An on-chip interconnect may be used to couple the I/O devices 1862 to the GPU 1880 and memory 1866. One or more I/O memory management units (IOMMUs) 1864 of the I/O circuitry 1863 couple the I/O devices 1862 directly to the system memory 1866. Optionally, the IOMMU 1864 manages multiple sets of page tables to map virtual addresses to physical addresses in system memory 1866. The I/O devices 1862, CPU(s) 1861, and GPU(s) 1880 may then share the same virtual address space.

In one implementation of the IOMMU 1864, the IOMMU 1864 supports virtualization. In this case, it may manage a first set of page tables to map guest/graphics virtual addresses to guest/graphics physical addresses and a second set of page tables to map the guest/graphics physical addresses to system/host physical addresses (e.g., within system memory 1866). The base addresses of each of the first and second sets of page tables may be stored in control registers and swapped out on a context switch (e.g., so that the new context is provided with access to the relevant set of page tables). While not illustrated in FIG. 18C, each of the cores 1870, 1871, 1872 and/or multi-core groups 1865A-1865N may include translation lookaside buffers (TLBs) to cache guest virtual to guest physical translations, guest physical to host physical translations, and guest virtual to host physical translations.

The CPU(s) 1861, GPUs 1880, and I/O devices 1862 may be integrated on a single semiconductor chip and/or chip package. The illustrated memory 1866 may be integrated on the same chip or may be coupled to the memory controllers 1867 via an off-chip interface. In one implementation, the memory 1866 comprises GDDR6 memory which shares the same virtual address space as other physical system-level memories, although the underlying principles described herein are not limited to this specific implementation.

The tensor cores 1871 may include a plurality of execution units specifically designed to perform matrix operations, which are the fundamental compute operation used to perform deep learning operations. For example, simultaneous matrix multiplication operations may be used for neural network training and inferencing. The tensor cores 1871 may perform matrix processing using a variety of operand precisions including single precision floating-point (e.g., 32 bits), half-precision floating point (e.g., 16 bits), integer words (16 bits), bytes (8 bits), and half-bytes (4 bits). For example, a neural network implementation extracts features of each rendered scene, potentially combining details from multiple frames, to construct a high-quality final image.

In deep learning implementations, parallel matrix multiplication work may be scheduled for execution on the tensor cores 1871. The training of neural networks, in particular, requires a significant number of matrix dot product operations. In order to process an inner-product formulation of an N×N×N matrix multiply, the tensor cores 1871 may include at least N dot-product processing elements. Before the matrix multiply begins, one entire matrix is loaded into tile registers and at least one column of a second matrix is loaded each cycle for N cycles. Each cycle, there are N dot products that are processed.

Matrix elements may be stored at different precisions depending on the particular implementation, including 16-bit words, 8-bit bytes (e.g., INT8) and 4-bit half-bytes (e.g., INT4). Different precision modes may be specified for the tensor cores 1871 to ensure that the most efficient precision is used for different workloads (e.g., such as inferencing workloads which can tolerate quantization to bytes and half-bytes). Supported formats additionally include 64-bit floating point (FP64) and non-IEEE floating point formats such as the bfloat 16 format (e.g., Brain floating point), a 16-bit floating point format with one sign bit, eight exponent bits, and eight significand bits, of which seven are explicitly stored. One example includes support for a reduced precision tensor-float (TF32) mode, which performs computations using the range of FP32 (8-bits) and the precision of FP16 (10-bits). Reduced precision TF32 operations can be performed on FP32 inputs and produce FP32 outputs at higher performance relative to FP32 and increased precision relative to FP16. In some examples, one or more 8-bit floating point formats (FP8) are supported.

In some examples the tensor cores 1871 support a sparse mode of operation for matrices in which the vast majority of values are zero. The tensor cores 1871 include support for sparse input matrices that are encoded in a sparse matrix representation (e.g., coordinate list encoding (COO), compressed sparse row (CSR), compress sparse column (CSC), etc.). The tensor cores 1871 also include support for compressed sparse matrix representations in the event that the sparse matrix representation may be further compressed. Compressed, encoded, and/or compressed and encoded matrix data, along with associated compression and/or encoding metadata, can be read by the tensor cores 1871 and the non-zero values can be extracted. For example, for a given input matrix A, a non-zero value can be loaded from the compressed and/or encoded representation of at least a portion of matrix A. Based on the location in matrix A for the non-zero value, which may be determined from index or coordinate metadata associated with the non-zero value, a corresponding value in input matrix B may be loaded. Depending on the operation to be performed (e.g., multiply), the load of the value from input matrix B may be bypassed if the corresponding value is a zero value. In some examples, the pairings of values for certain operations, such as multiply operations, may be pre-scanned by scheduler logic and only operations between non-zero inputs are scheduled. Depending on the dimensions of matrix A and matrix B and the operation to be performed, output matrix C may be dense or sparse. Where output matrix C is sparse and depending on the configuration of the tensor cores 1871, output matrix C may be output in a compressed format, a sparse encoding, or a compressed sparse encoding.

The ray tracing cores 1872 may accelerate ray tracing operations for both real-time ray tracing and non-real-time ray tracing implementations. In particular, the ray tracing cores 1872 may include ray traversal/intersection circuitry for performing ray traversal using bounding volume hierarchies (BVHs) and identifying intersections between rays and primitives enclosed within the BVH volumes. The ray tracing cores 1872 may also include circuitry for performing depth testing and culling (e.g., using a Z buffer or similar arrangement). In one implementation, the ray tracing cores 1872 perform traversal and intersection operations in concert with the image denoising techniques described herein, at least a portion of which may be executed on the tensor cores 1871. For example, the tensor cores 1871 may implement a deep learning neural network to perform denoising of frames generated by the ray tracing cores 1872. However, the CPU(s) 1861, graphics cores 1870, and/or ray tracing cores 1872 may also implement all or a portion of the denoising and/or deep learning algorithms.

In addition, as described above, a distributed approach to denoising may be employed in which the GPU 1880 is in a computing device coupled to other computing devices over a network or high-speed interconnect. In this distributed approach, the interconnected computing devices may share neural network learning/training data to improve the speed with which the overall system learns to perform denoising for different types of image frames and/or different graphics applications.

The ray tracing cores 1872 may process all BVH traversal and/or ray-primitive intersections, saving the graphics cores 1870 from being overloaded with thousands of instructions per ray. For example, each ray tracing core 1872 includes a first set of specialized circuitry for performing bounding box tests (e.g., for traversal operations) and/or a second set of specialized circuitry for performing the ray-triangle intersection tests (e.g., intersecting rays which have been traversed). Thus, for example, the multi-core group 1865A can simply launch a ray probe, and the ray tracing cores 1872 independently perform ray traversal and intersection and return hit data (e.g., a hit, no hit, multiple hits, etc.) to the thread context. The other cores 1870, 1871 are freed to perform other graphics or compute work while the ray tracing cores 1872 perform the traversal and intersection operations.

Optionally, each ray tracing core 1872 may include a traversal unit to perform BVH testing operations and/or an intersection unit which performs ray-primitive intersection tests. The intersection unit generates a “hit”, “no hit”, or “multiple hit” response, which it provides to the appropriate thread. During the traversal and intersection operations, the execution resources of the other cores (e.g., graphics cores 1870 and tensor cores 1871) are freed to perform other forms of graphics work.

In some examples described below, a hybrid rasterization/ray tracing approach is used in which work is distributed between the graphics cores 1870 and ray tracing cores 1872.

The ray tracing cores 1872 (and/or other cores 1870, 1871) may include hardware support for a ray tracing instruction set such as Microsoft's DirectX Ray Tracing (DXR) which includes a DispatchRays command, as well as ray-generation, closest-hit, any-hit, and miss shaders, which enable the assignment of unique sets of shaders and textures for each object. Another ray tracing platform which may be supported by the ray tracing cores 1872, graphics cores 1870 and tensor cores 1871 is Vulkan API (e.g., Vulkan version 1.1.85 and later). Note, however, that the underlying principles described herein are not limited to any particular ray tracing ISA.

In general, the various cores 1872, 1871, 1870 may support a ray tracing instruction set that includes instructions/functions for one or more of ray generation, closest hit, any hit, ray-primitive intersection, per-primitive and hierarchical bounding box construction, miss, visit, and exceptions. More specifically, some examples includes ray tracing instructions to perform one or more of the following functions:
Ray Generation-Ray generation instructions may be executed for each pixel, sample, or other user-defined work assignment.
Closest Hit-A closest hit instruction may be executed to locate the closest intersection point of a ray with primitives within a scene.
Any Hit—An any hit instruction identifies multiple intersections between a ray and primitives within a scene, potentially to identify a new closest intersection point.
Intersection—An intersection instruction performs a ray-primitive intersection test and outputs a result.
Per-primitive Bounding box Construction—This instruction builds a bounding box around a given primitive or group of primitives (e.g., when building a new BVH or other acceleration data structure).
Miss-Indicates that a ray misses all geometry within a scene, or specified region of a scene.
Visit-Indicates the child volumes a ray will traverse.
Exceptions-Includes various types of exception handlers (e.g., invoked for various error conditions).

In some examples the ray tracing cores 1872 may be adapted to accelerate general-purpose compute operations that can be accelerated using computational techniques that are analogous to ray intersection tests. A compute framework can be provided that enables shader programs to be compiled into low level instructions and/or primitives that perform general-purpose compute operations via the ray tracing cores. Exemplary computational problems that can benefit from compute operations performed on the ray tracing cores 1872 include computations involving beam, wave, ray, or particle propagation within a coordinate space. Interactions associated with that propagation can be computed relative to a geometry or mesh within the coordinate space. For example, computations associated with electromagnetic signal propagation through an environment can be accelerated via the use of instructions or primitives that are executed via the ray tracing cores. Diffraction and reflection of the signals by objects in the environment can be computed as direct ray-tracing analogies.

Ray tracing cores 1872 can also be used to perform computations that are not directly analogous to ray tracing. For example, mesh projection, mesh refinement, and volume sampling computations can be accelerated using the ray tracing cores 1872. Generic coordinate space calculations, such as nearest neighbor calculations can also be performed. For example, the set of points near a given point can be discovered by defining a bounding box in the coordinate space around the point. BVH and ray probe logic within the ray tracing cores 1872 can then be used to determine the set of point intersections within the bounding box. The intersections constitute the origin point and the nearest neighbors to that origin point. Computations that are performed using the ray tracing cores 1872 can be performed in parallel with computations performed on the graphics cores 1872 and tensor cores 1871. A shader compiler can be configured to compile a compute shader or other general-purpose graphics processing program into low level primitives that can be parallelized across the graphics cores 1870, tensor cores 1871, and ray tracing cores 1872.

Building larger and larger silicon dies is challenging for a variety of reasons. As silicon dies become larger, manufacturing yields become smaller and process technology requirements for different components may diverge. On the other hand, in order to have a high-performance system, key components should be interconnected by high speed, high bandwidth, low latency interfaces. These contradicting needs pose a challenge to high performance chip development.

Embodiments described herein provide techniques to disaggregate an architecture of a system on a chip integrated circuit into multiple distinct chiplets that can be packaged onto a common chassis. In some examples, a graphics processing unit or parallel processor is composed from diverse silicon chiplets that are separately manufactured. A chiplet is an at least partially packaged integrated circuit that includes distinct units of logic that can be assembled with other chiplets into a larger package. A diverse set of chiplets with different IP core logic can be assembled into a single device. Additionally the chiplets can be integrated into a base die or base chiplet using active interposer technology. The concepts described herein enable the interconnection and communication between the different forms of IP within the GPU. The development of IPs on different process may be mixed. This avoids the complexity of converging multiple IPs, especially on a large SoC with several flavors IPs, to the same process.

Enabling the use of multiple process technologies improves the time to market and provides a cost-effective way to create multiple product SKUs. For customers, this means getting products that are more tailored to their requirements in a cost effective and timely manner. Additionally, the disaggregated IPs are more amenable to being power gated independently, components that are not in use on a given workload can be powered off, reducing overall power consumption.

Example Core Architectures-In-order and out-of-order core block diagram.

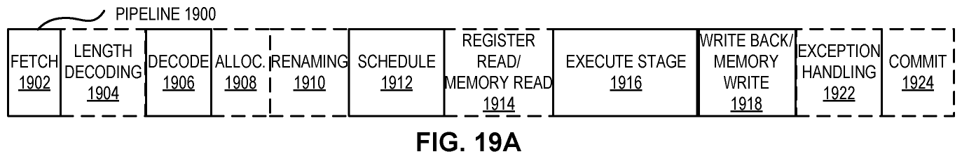

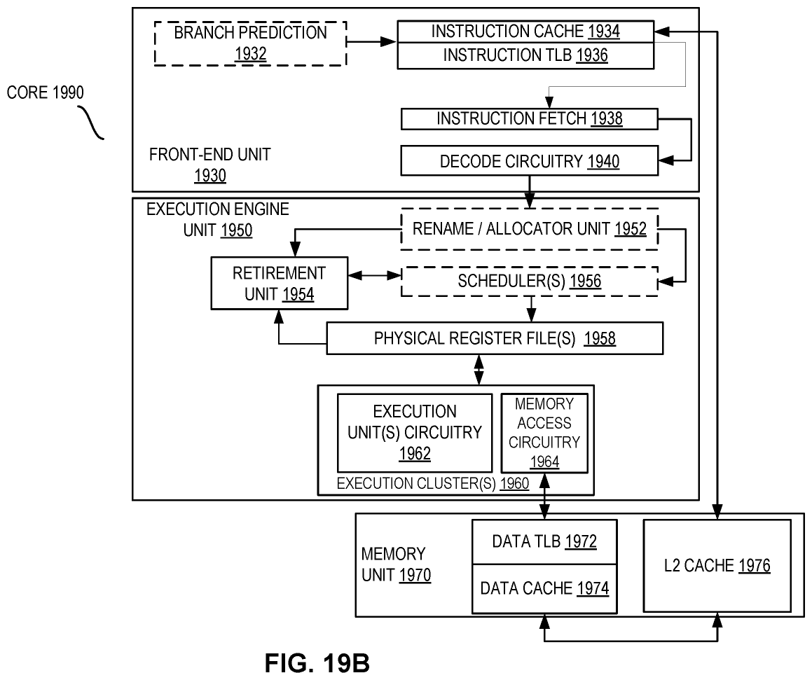

FIG. 19A is a block diagram illustrating both an example in-order pipeline and an example register renaming, out-of-order issue/execution pipeline according to examples. FIG. 19B is a block diagram illustrating both an example in-order architecture core and an example register renaming, out-of-order issue/execution architecture core to be included in a processor according to examples. The solid lined boxes in FIGS. 19A-(B) illustrate the in-order pipeline and in-order core, while the optional addition of the dashed lined boxes illustrates the register renaming, out-of-order issue/execution pipeline and core. Given that the in-order aspect is a subset of the out-of-order aspect, the out-of-order aspect will be described.

In FIG. 19A, a processor pipeline 1900 includes a fetch stage 1902, an optional length decoding stage 1904, a decode stage 1906, an optional allocation (Alloc) stage 1908, an optional renaming stage 1910, a schedule (also known as a dispatch or issue) stage 1912, an optional register read/memory read stage 1914, an execute stage 1916, a write back/memory write stage 1918, an optional exception handling stage 1922, and an optional commit stage 1924. One or more operations can be performed in each of these processor pipeline stages. For example, during the fetch stage 1902, one or more instructions are fetched from instruction memory, and during the decode stage 1906, the one or more fetched instructions may be decoded, addresses (e.g., load store unit (LSU) addresses) using forwarded register ports may be generated, and branch forwarding (e.g., immediate offset or a link register (LR)) may be performed. In some examples, the decode stage 1906 and the register read/memory read stage 1914 may be combined into one pipeline stage. In some examples, during the execute stage 1916, the decoded instructions may be executed, LSU address/data pipelining to an Advanced Microcontroller Bus (AMB) interface may be performed, multiply and add operations may be performed, arithmetic operations with branch results may be performed, etc.

By way of example, the example register renaming, out-of-order issue/execution architecture core of FIG. 19B may implement the pipeline 1900 as follows: 1) the instruction fetch circuitry 1938 performs the fetch and length decoding stages 1902 and 1904; 2) the decode circuitry 1940 performs the decode stage 1906; 3) the rename/allocator unit circuitry 1952 performs the allocation stage 1908 and renaming stage 1910; 4) the scheduler(s) circuitry 1956 performs the schedule stage 1912; 5) the physical register file(s) circuitry 1958 and the memory unit circuitry 1970 perform the register read/memory read stage 1914; the execution cluster(s) 1960 perform the execute stage 1916; 6) the memory unit circuitry 1970 and the physical register file(s) circuitry 1958 perform the write back/memory write stage 1918; 7) various circuitry may be involved in the exception handling stage 1922; and 8) the retirement unit circuitry 1954 and the physical register file(s) circuitry 1958 perform the commit stage 1924.

FIG. 19B shows a processor core 1990 including front-end unit circuitry 1930 coupled to execution engine unit circuitry 1950, and both are coupled to memory unit circuitry 1970. The core 1990 may be a reduced instruction set architecture computing (RISC) core, a complex instruction set architecture computing (CISC) core, a very long instruction word (VLIW) core, or a hybrid or alternative core type. As yet another option, the core 1990 may be a special-purpose core, such as, for example, a network or communication core, compression engine, coprocessor core, general purpose computing graphics processing unit (GPGPU) core, graphics core, or the like.

The front-end unit circuitry 1930 may include branch prediction circuitry 1932 coupled to instruction cache circuitry 1934, which is coupled to an instruction translation lookaside buffer (TLB) 1936, which is coupled to instruction fetch circuitry 1938, which is coupled to decode circuitry 1940. In some examples, the instruction cache circuitry 1934 is included in the memory unit circuitry 1970 rather than the front-end circuitry 1930. The decode circuitry 1940 (or decoder) may decode instructions, and generate as an output one or more micro-operations, micro-code entry points, microinstructions, other instructions, or other control signals, which are decoded from, or which otherwise reflect, or are derived from, the original instructions. The decode circuitry 1940 may further include address generation unit (AGU, not shown) circuitry. In some examples, the AGU generates an LSU address using forwarded register ports, and may further perform branch forwarding (e.g., immediate offset branch forwarding, LR register branch forwarding, etc.). The decode circuitry 1940 may be implemented using various different mechanisms. Examples of suitable mechanisms include, but are not limited to, look-up tables, hardware implementations, programmable logic arrays (PLAs), microcode read only memories (ROMs), etc. In some examples, the core 1990 includes a microcode ROM (not shown) or other medium that stores microcode for certain macroinstructions (e.g., in decode circuitry 1940 or otherwise within the front-end circuitry 1930). In some examples, the decode circuitry 1940 includes a micro-operation (micro-op) or operation cache (not shown) to hold/cache decoded operations, micro-tags, or micro-operations generated during the decode or other stages of the processor pipeline 1900. The decode circuitry 1940 may be coupled to rename/allocator unit circuitry 1952 in the execution engine circuitry 1950.

The execution engine circuitry 1950 includes the rename/allocator unit circuitry 1952 coupled to retirement unit circuitry 1954 and a set of one or more scheduler(s) circuitry 1956. The scheduler(s) circuitry 1956 represents any number of different schedulers, including reservations stations, central instruction window, etc. In some examples, the scheduler(s) circuitry 1956 can include arithmetic logic unit (ALU) scheduler/scheduling circuitry, ALU queues, address generation unit (AGU) scheduler/scheduling circuitry, AGU queues, etc. The scheduler(s) circuitry 1956 is coupled to the physical register file(s) circuitry 1958. Each of the physical register file(s) circuitry 1958 represents one or more physical register files, different ones of which store one or more different data types, such as scalar integer, scalar floating-point, packed integer, packed floating-point, vector integer, vector floating-point, status (e.g., an instruction pointer that is the address of the next instruction to be executed), etc. In some examples, the physical register file(s) circuitry 1958 includes vector registers unit circuitry, writemask registers unit circuitry, and scalar register unit circuitry. These register units may provide architectural vector registers, vector mask registers, general-purpose registers, etc. The physical register file(s) circuitry 1958 is coupled to the retirement unit circuitry 1954 (also known as a retire queue or a retirement queue) to illustrate various ways in which register renaming and out-of-order execution may be implemented (e.g., using a reorder buffer(s) (ROB(s)) and a retirement register file(s); using a future file(s), a history buffer(s), and a retirement register file(s); using a register maps and a pool of registers; etc.). The retirement unit circuitry 1954 and the physical register file(s) circuitry 1958 are coupled to the execution cluster(s) 1960. The execution cluster(s) 1960 includes a set of one or more execution unit(s) circuitry 1962 and a set of one or more memory access circuitry 1964. The execution unit(s) circuitry 1962 may perform various arithmetic, logic, floating-point or other types of operations (e.g., shifts, addition, subtraction, multiplication) and on various types of data (e.g., scalar integer, scalar floating-point, packed integer, packed floating-point, vector integer, vector floating-point). While some examples may include a number of execution units or execution unit circuitry dedicated to specific functions or sets of functions, other examples may include only one execution unit circuitry or multiple execution units/execution unit circuitry that all perform all functions. The scheduler(s) circuitry 1956, physical register file(s) circuitry 1958, and execution cluster(s) 1960 are shown as being possibly plural because certain examples create separate pipelines for certain types of data/operations (e.g., a scalar integer pipeline, a scalar floating-point/packed integer/packed floating-point/vector integer/vector floating-point pipeline, and/or a memory access pipeline that each have their own scheduler circuitry, physical register file(s) circuitry, and/or execution cluster—and in the case of a separate memory access pipeline, certain examples are implemented in which only the execution cluster of this pipeline has the memory access unit(s) circuitry 1964). It should also be understood that where separate pipelines are used, one or more of these pipelines may be out-of-order issue/execution and the rest in-order.

In some examples, the execution engine unit circuitry 1950 may perform load store unit (LSU) address/data pipelining to an Advanced Microcontroller Bus (AMB) interface (not shown), and address phase and writeback, data phase load, store, and branches.

The set of memory access circuitry 1964 is coupled to the memory unit circuitry 1970, which includes data TLB circuitry 1972 coupled to data cache circuitry 1974 coupled to level 2 (L2) cache circuitry 1976. In some examples, the memory access circuitry 1964 may include load unit circuitry, store address unit circuitry, and store data unit circuitry, each of which is coupled to the data TLB circuitry 1972 in the memory unit circuitry 1970. The instruction cache circuitry 1934 is further coupled to the level 2 (L2) cache circuitry 1976 in the memory unit circuitry 1970. In some examples, the instruction cache 1934 and the data cache 1974 are combined into a single instruction and data cache (not shown) in L2 cache circuitry 1976, level 3 (L3) cache circuitry (not shown), and/or main memory. The L2 cache circuitry 1976 is coupled to one or more other levels of cache and eventually to a main memory.

The core 1990 may support one or more instructions sets (e.g., the x86 instruction set architecture (optionally with some extensions that have been added with newer versions); the MIPS instruction set architecture; the ARM instruction set architecture (optionally with optional additional extensions such as NEON)), including the instruction(s) described herein. In some examples, the core 1990 includes logic to support a packed data instruction set architecture extension (e.g., AVX1, AVX2), thereby allowing the operations used by many multimedia applications to be performed using packed data.

### Exemplary Execution Unit(s) Circuitry

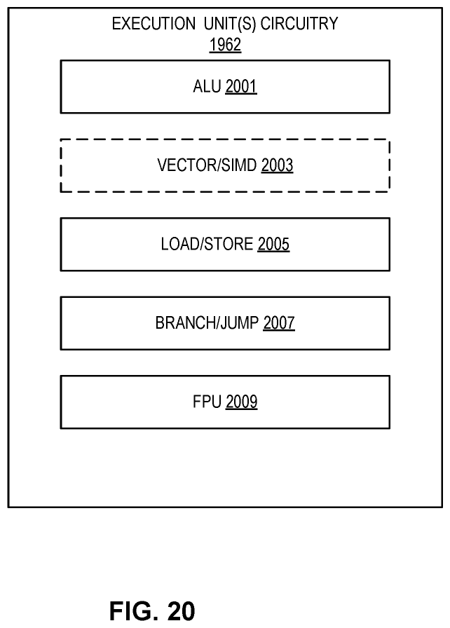

FIG. 20 illustrates examples of execution unit(s) circuitry, such as execution unit(s) circuitry 1962 of FIG. 19B. As illustrated, execution unit(s) circuitry 1962 may include one or more ALU circuits 2001, optional vector/single instruction multiple data (SIMD) circuits 2003, load/store circuits 2005, branch/jump circuits 2007, and/or Floating-point unit (FPU) circuits 2009. ALU circuits 2001 perform integer arithmetic and/or Boolean operations. Vector/SIMD circuits 2003 perform vector/SIMD operations on packed data (such as SIMD/vector registers). Load/store circuits 2005 execute load and store instructions to load data from memory into registers or store from registers to memory. Load/store circuits 2005 may also generate addresses. Branch/jump circuits 2007 cause a branch or jump to a memory address depending on the instruction. FPU circuits 2009 perform floating-point arithmetic. The width of the execution unit(s) circuitry 1962 varies depending upon the example and can range from 16-bit to 1,024-bit, for example. In some examples, two or more smaller execution units are logically combined to form a larger execution unit (e.g., two 128-bit execution units are logically combined to form a 256-bit execution unit).

FIGS. 21A-21B illustrate thread execution logic 2100 including an array of processing elements employed in a graphics processor core according to examples described herein. Elements of FIGS. 21A-21B having the same reference numbers (or names) as the elements of any other figure herein can operate or function in any manner similar to that described elsewhere herein, but are not limited to such. FIG. 21A is representative of an execution unit within a general-purpose graphics processor, while FIG. 21B is representative of an execution unit that may be used within a compute accelerator.

As illustrated in FIG. 21A, in some examples thread execution logic 2100 includes a shader processor 2102, a thread dispatcher 2104, instruction cache 2106, a scalable execution unit array including a plurality of execution units 2108A-2108N, a sampler 2110, shared local memory 2111, a data cache 2112, and a data port 2114. In some examples the scalable execution unit array can dynamically scale by enabling or disabling one or more execution units (e.g., any of execution units 2108A, 2108B, 2108C, 2108D, through 2108N-1 and 2108N) based on the computational requirements of a workload. In some examples the included components are interconnected via an interconnect fabric that links to each of the components. In some examples, thread execution logic 2100 includes one or more connections to memory, such as system memory or cache memory, through one or more of instruction cache 2106, data port 2114, sampler 2110, and execution units 2108A-2108N. In some examples, each execution unit (e.g. 2108A) is a stand-alone programmable general-purpose computational unit that is capable of executing multiple simultaneous hardware threads while processing multiple data elements in parallel for each thread. In various examples, the array of execution units 2108A-2108N is scalable to include any number individual execution units.

In some examples, the execution units 2108A-2108N are primarily used to execute shader programs. A shader processor 2102 can process the various shader programs and dispatch execution threads associated with the shader programs via a thread dispatcher 2104. In some examples the thread dispatcher includes logic to arbitrate thread initiation requests from the graphics and media pipelines and instantiate the requested threads on one or more execution unit in the execution units 2108A-2108N. For example, a geometry pipeline can dispatch vertex, tessellation, or geometry shaders to the thread execution logic for processing. In some examples, thread dispatcher 2104 can also process runtime thread spawning requests from the executing shader programs.

In some examples, the execution units 2108A-2108N support an instruction set that includes native support for many standard 3D graphics shader instructions, such that shader programs from graphics libraries (e.g., Direct 3D and OpenGL) are executed with a minimal translation. The execution units support vertex and geometry processing (e.g., vertex programs, geometry programs, vertex shaders), pixel processing (e.g., pixel shaders, fragment shaders) and general-purpose processing (e.g., compute and media shaders). Each of the execution units 2108A-2108N is capable of multi-issue single instruction multiple data (SIMD) execution and multi-threaded operation enables an efficient execution environment in the face of higher latency memory accesses. Each hardware thread within each execution unit has a dedicated high-bandwidth register file and associated independent thread-state. Execution is multi-issue per clock to pipelines capable of integer, single and double precision floating point operations, SIMD branch capability, logical operations, transcendental operations, and other miscellaneous operations. While waiting for data from memory or one of the shared functions, dependency logic within the execution units 2108A-2108N causes a waiting thread to sleep until the requested data has been returned. While the waiting thread is sleeping, hardware resources may be devoted to processing other threads. For example, during a delay associated with a vertex shader operation, an execution unit can perform operations for a pixel shader, fragment shader, or another type of shader program, including a different vertex shader. Various examples can apply to use execution by use of Single Instruction Multiple Thread (SIMT) as an alternate to use of SIMD or in addition to use of SIMD. Reference to a SIMD core or operation can apply also to SIMT or apply to SIMD in combination with SIMT.

Each execution unit in execution units 2108A-2108N operates on arrays of data elements. The number of data elements is the “execution size,” or the number of channels for the instruction. An execution channel is a logical unit of execution for data element access, masking, and flow control within instructions. The number of channels may be independent of the number of physical Arithmetic Logic Units (ALUs) or Floating Point Units (FPUs) for a particular graphics processor. In some examples, execution units 2108A-2108N support integer and floating-point data types.

The execution unit instruction set includes SIMD instructions. The various data elements can be stored as a packed data type in a register and the execution unit will process the various elements based on the data size of the elements. For example, when operating on a 256-bit wide vector, the 256 bits of the vector are stored in a register and the execution unit operates on the vector as four separate 64-bit packed data elements (Quad-Word (QW) size data elements), eight separate 32-bit packed data elements (Double Word (DW) size data elements), sixteen separate 16-bit packed data elements (Word (W) size data elements), or thirty-two separate 8-bit data elements (byte (B) size data elements). However, different vector widths and register sizes are possible.

In some examples one or more execution units can be combined into a fused execution unit 2109A-2109N having thread control logic (2107A-2107N) that is common to the fused EUs. Multiple EUs can be fused into an EU group. Each EU in the fused EU group can be configured to execute a separate SIMD hardware thread. The number of EUs in a fused EU group can vary according to examples. Additionally, various SIMD widths can be performed per-EU, including but not limited to SIMD8, SIMD16, and SIMD32. Each fused graphics execution unit 2109A-2109N includes at least two execution units. For example, fused execution unit 2109A includes a first EU 2108A, second EU 2108B, and thread control logic 2107A that is common to the first EU 2108A and the second EU 2108B. The thread control logic 2107A controls threads executed on the fused graphics execution unit 2109A, allowing each EU within the fused execution units 2109A-2109N to execute using a common instruction pointer register.

One or more internal instruction caches (e.g., 2106) are included in the thread execution logic 2100 to cache thread instructions for the execution units. In some examples, one or more data caches (e.g., 2112) are included to cache thread data during thread execution. Threads executing on the execution logic 2100 can also store explicitly managed data in the shared local memory 2111. In some examples, a sampler 2110 is included to provide texture sampling for 3D operations and media sampling for media operations. In some examples, sampler 2110 includes specialized texture or media sampling functionality to process texture or media data during the sampling process before providing the sampled data to an execution unit.

During execution, the graphics and media pipelines send thread initiation requests to thread execution logic 2100 via thread spawning and dispatch logic. Once a group of geometric objects has been processed and rasterized into pixel data, pixel processor logic (e.g., pixel shader logic, fragment shader logic, etc.) within the shader processor 2102 is invoked to further compute output information and cause results to be written to output surfaces (e.g., color buffers, depth buffers, stencil buffers, etc.). In some examples, a pixel shader or fragment shader calculates the values of the various vertex attributes that are to be interpolated across the rasterized object. In some examples, pixel processor logic within the shader processor 2102 then executes an application programming interface (API)-supplied pixel or fragment shader program. To execute the shader program, the shader processor 2102 dispatches threads to an execution unit (e.g., 2108A) via thread dispatcher 2104. In some examples, shader processor 2102 uses texture sampling logic in the sampler 2110 to access texture data in texture maps stored in memory. Arithmetic operations on the texture data and the input geometry data compute pixel color data for each geometric fragment, or discards one or more pixels from further processing.

In some examples, the data port 2114 provides a memory access mechanism for the thread execution logic 2100 to output processed data to memory for further processing on a graphics processor output pipeline. In some examples, the data port 2114 includes or couples to one or more cache memories (e.g., data cache 2112) to cache data for memory access via the data port.

In some examples, the execution logic 2100 can also include a ray tracer 2105 that can provide ray tracing acceleration functionality. The ray tracer 2105 can support a ray tracing instruction set that includes instructions/functions for ray generation.

FIG. 21B illustrates exemplary internal details of an execution unit 2108, according to examples. A graphics execution unit 2108 can include an instruction fetch unit 2137, a general register file array (GRF) 2124, an architectural register file array (ARF) 2126, a thread arbiter 2122, a send unit 2130, a branch unit 2132, a set of SIMD floating point units (FPUs) 2134, and in some examples a set of dedicated integer SIMD ALUs 2135. The GRF 2124 and ARF 2126 includes the set of general register files and architecture register files associated with each simultaneous hardware thread that may be active in the graphics execution unit 2108. In some examples, per thread architectural state is maintained in the ARF 2126, while data used during thread execution is stored in the GRF 2124. The execution state of each thread, including the instruction pointers for each thread, can be held in thread-specific registers in the ARF 2126.

In some examples the graphics execution unit 2108 has an architecture that is a combination of Simultaneous Multi-Threading (SMT) and fine-grained Interleaved Multi-Threading (IMT). The architecture has a modular configuration that can be fine-tuned at design time based on a target number of simultaneous threads and number of registers per execution unit, where execution unit resources are divided across logic used to execute multiple simultaneous threads. The number of logical threads that may be executed by the graphics execution unit 2108 is not limited to the number of hardware threads, and multiple logical threads can be assigned to each hardware thread.

In some examples, the graphics execution unit 2108 can co-issue multiple instructions, which may each be different instructions. The thread arbiter 2122 of the graphics execution unit thread 2108 can dispatch the instructions to one of the send unit 2130, branch unit 2132, or SIMD FPU(s) 2134 for execution. Each execution thread can access 128 general-purpose registers within the GRF 2124, where each register can store 32 bytes, accessible as a SIMD 8-element vector of 32-bit data elements. In some examples, each execution unit thread has access to 4 Kbytes within the GRF 2124, although examples are not so limited, and greater or fewer register resources may be provided in other examples. In some examples the graphics execution unit 2108 is partitioned into seven hardware threads that can independently perform computational operations, although the number of threads per execution unit can also vary according to examples. For example, in some examples up to 16 hardware threads are supported. In an example in which seven threads may access 4 Kbytes, the GRF 2124 can store a total of 28 Kbytes. Where 16 threads may access 4 Kbytes, the GRF 2124 can store a total of 64 Kbytes. Flexible addressing modes can permit registers to be addressed together to build effectively wider registers or to represent strided rectangular block data structures.

In some examples, memory operations, sampler operations, and other longer-latency system communications are dispatched via “send” instructions that are executed by the message passing send unit 2130. In some examples, branch instructions are dispatched to a dedicated branch unit 2132 to facilitate SIMD divergence and eventual convergence.

In some examples the graphics execution unit 2108 includes one or more SIMD floating point units (FPU(s)) 2134 to perform floating-point operations. In some examples, the FPU(s) 2134 also support integer computation. In some examples the FPU(s) 2134 can SIMD execute up to M number of 32-bit floating-point (or integer) operations, or SIMD execute up to 2M 16-bit integer or 16-bit floating-point operations. In some examples, at least one of the FPU(s) provides extended math capability to support high-throughput transcendental math functions and double precision 64-bit floating-point. In some examples, a set of 8-bit integer SIMD ALUs 2135 are also present, and may be specifically optimized to perform operations associated with machine learning computations.

In some examples, arrays of multiple instances of the graphics execution unit 2108 can be instantiated in a graphics sub-core grouping (e.g., a sub-slice). For scalability, product architects can choose the exact number of execution units per sub-core grouping. In some examples the execution unit 2108 can execute instructions across a plurality of execution channels. In a further example, each thread executed on the graphics execution unit 2108 is executed on a different channel.

### Graphics Pipeline

FIG. 22 is a block diagram of another example of a graphics processor 2200. Elements of FIG. 22 having the same reference numbers (or names) as the elements of any other figure herein can operate or function in any manner similar to that described elsewhere herein, but are not limited to such.

In some examples, graphics processor 2200 includes a geometry pipeline 2220, a media pipeline 2230, a display engine 2240, thread execution logic 2250, and a render output pipeline 2270. In some examples, graphics processor 2200 is a graphics processor within a multi-core processing system that includes one or more general-purpose processing cores. The graphics processor is controlled by register writes to one or more control registers (not shown) or via commands issued to graphics processor 2200 via a ring interconnect 2202. In some examples, ring interconnect 2202 couples graphics processor 2200 to other processing components, such as other graphics processors or general-purpose processors. Commands from ring interconnect 2202 are interpreted by a command streamer 2203, which supplies instructions to individual components of the geometry pipeline 2220 or the media pipeline 2230.

In some examples, command streamer 2203 directs the operation of a vertex fetcher 2205 that reads vertex data from memory and executes vertex-processing commands provided by command streamer 2203. In some examples, vertex fetcher 2205 provides vertex data to a vertex shader 2207, which performs coordinate space transformation and lighting operations to each vertex. In some examples, vertex fetcher 2205 and vertex shader 2207 execute vertex-processing instructions by dispatching execution threads to execution units 2252A-2252B via a thread dispatcher 2231.

In some examples, execution units 2252A-2252B are an array of vector processors having an instruction set for performing graphics and media operations. In some examples, execution units 2252A-2252B have an attached L1 cache 2251 that is specific for each array or shared between the arrays. The cache can be configured as a data cache, an instruction cache, or a single cache that is partitioned to contain data and instructions in different partitions.

In some examples, geometry pipeline 2220 includes tessellation components to perform hardware-accelerated tessellation of 3D objects. In some examples, a programmable hull shader 2211 configures the tessellation operations. A programmable domain shader 2217 provides back-end evaluation of tessellation output. A tessellator 2213 operates at the direction of hull shader 2211 and contains special purpose logic to generate a set of detailed geometric objects based on a coarse geometric model that is provided as input to geometry pipeline 2220. In some examples, if tessellation is not used, tessellation components (e.g., hull shader 2211, tessellator 2213, and domain shader 2217) can be bypassed.

In some examples, complete geometric objects can be processed by a geometry shader 2219 via one or more threads dispatched to execution units 2252A-2252B, or can proceed directly to the clipper 2229. In some examples, the geometry shader operates on entire geometric objects, rather than vertices or patches of vertices as in previous stages of the graphics pipeline. If the tessellation is disabled the geometry shader 2219 receives input from the vertex shader 2207. In some examples, geometry shader 2219 is programmable by a geometry shader program to perform geometry tessellation if the tessellation units are disabled.

Before rasterization, a clipper 2229 processes vertex data. The clipper 2229 may be a fixed function clipper or a programmable clipper having clipping and geometry shader functions. In some examples, a rasterizer and depth test component 2273 in the render output pipeline 2270 dispatches pixel shaders to convert the geometric objects into per pixel representations. In some examples, pixel shader logic is included in thread execution logic 2250. In some examples, an application can bypass the rasterizer and depth test component 2273 and access un-rasterized vertex data via a stream out unit 2223.

The graphics processor 2200 has an interconnect bus, interconnect fabric, or some other interconnect mechanism that allows data and message passing amongst the major components of the processor. In some examples, execution units 2252A-2252B and associated logic units (e.g., L1 cache 2251, sampler 2254, texture cache 2258, etc.) interconnect via a data port 2256 to perform memory access and communicate with render output pipeline components of the processor. In some examples, sampler 2254, caches 2251, 2258 and execution units 2252A-2252B each have separate memory access paths. In some examples the texture cache 2258 can also be configured as a sampler cache.

In some examples, render output pipeline 2270 contains a rasterizer and depth test component 2273 that converts vertex-based objects into an associated pixel-based representation. In some examples, the rasterizer logic includes a windower/masker unit to perform fixed function triangle and line rasterization. An associated render cache 2278 and depth cache 2279 are also available in some examples. A pixel operations component 2277 performs pixel-based operations on the data, though in some instances, pixel operations associated with 2D operations (e.g. bit block image transfers with blending) are performed by the 2D engine 2241, or substituted at display time by the display controller 2243 using overlay display planes. In some examples, a shared L3 cache 2275 is available to all graphics components, allowing the sharing of data without the use of main system memory.

In some examples, graphics processor media pipeline 2230 includes a media engine 2237 and a video front-end 2234. In some examples, video front-end 2234 receives pipeline commands from the command streamer 2203. In some examples, media pipeline 2230 includes a separate command streamer. In some examples, video front-end 2234 processes media commands before sending the command to the media engine 2237. In some examples, media engine 2237 includes thread spawning functionality to spawn threads for dispatch to thread execution logic 2250 via thread dispatcher 2231.

In some examples, graphics processor 2200 includes a display engine 2240. In some examples, display engine 2240 is external to processor 2200 and couples with the graphics processor via the ring interconnect 2202, or some other interconnect bus or fabric. In some examples, display engine 2240 includes a 2D engine 2241 and a display controller 2243. In some examples, display engine 2240 contains special purpose logic capable of operating independently of the 3D pipeline. In some examples, display controller 2243 couples with a display device (not shown), which may be a system integrated display device, as in a laptop computer, or an external display device attached via a display device connector.

In some examples, the geometry pipeline 2220 and media pipeline 2230 are configurable to perform operations based on multiple graphics and media programming interfaces and are not specific to any one application programming interface (API). In some examples, driver software for the graphics processor translates API calls that are specific to a particular graphics or media library into commands that can be processed by the graphics processor. In some examples, support is provided for the Open Graphics Library (OpenGL), Open Computing Language (OpenCL), and/or Vulkan graphics and compute API, all from the Khronos Group. In some examples, support may also be provided for the Direct3D library from the Microsoft Corporation. In some examples, a combination of these libraries may be supported. Support may also be provided for the Open Source Computer Vision Library (OpenCV). A future API with a compatible 3D pipeline would also be supported if a mapping can be made from the pipeline of the future API to the pipeline of the graphics processor.

Program code may be applied to input information to perform the functions described herein and generate output information. The output information may be applied to one or more output devices, in known fashion. For purposes of this application, a processing system includes any system that has a processor, such as, for example, a digital signal processor (DSP), a microcontroller, an application specific integrated circuit (ASIC), a field programmable gate array (FPGA), a microprocessor, or any combination thereof.

The program code may be implemented in a high-level procedural or object-oriented programming language to communicate with a processing system. The program code may also be implemented in assembly or machine language, if desired. In fact, the mechanisms described herein are not limited in scope to any particular programming language. In any case, the language may be a compiled or interpreted language.

Examples of the mechanisms disclosed herein may be implemented in hardware, software, firmware, or a combination of such implementation approaches. Examples may be implemented as computer programs or program code executing on programmable systems comprising at least one processor, a storage system (including volatile and non-volatile memory and/or storage elements), at least one input device, and at least one output device.

Such machine-readable storage media may include, without limitation, non-transitory, tangible arrangements of articles manufactured or formed by a machine or device, including storage media such as hard disks, any other type of disk including floppy disks, optical disks, compact disk read-only memories (CD-ROMs), compact disk rewritables (CD-RWs), and magneto-optical disks, semiconductor devices such as read-only memories (ROMs), random access memories (RAMs) such as dynamic random access memories (DRAMs), static random access memories (SRAMs), erasable programmable read-only memories (EPROMs), flash memories, electrically erasable programmable read-only memories (EEPROMs), phase change memory (PCM), magnetic or optical cards, or any other type of media suitable for storing electronic instructions.

Accordingly, examples also include non-transitory, tangible machine-readable media containing instructions or containing design data, such as Hardware Description Language (HDL), which defines structures, circuits, apparatuses, processors and/or system features described herein. Such examples may also be referred to as program products.

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

An embodiment is an implementation or example of the disclosure. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the disclosure. The various appearances “an embodiment,” “one embodiment,” or “some embodiments” are not necessarily all referring to the same embodiments.

Not all components, features, structures, characteristics, etc. described and illustrated herein need to be included in a particular embodiment or embodiments. If the specification states a component, feature, structure, or characteristic “may”, “might”, “can”, or “could” be included, for example, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

The above description of illustrated embodiments of the disclosure, including what is described in the Abstract, is not intended to be exhaustive or to limit the disclosure to the precise forms disclosed. While specific embodiments of, and examples for, the disclosure are described herein for illustrative purposes, various equivalent modifications are possible within the scope of the disclosure, as those skilled in the relevant art will recognize.

These modifications can be made to the disclosure in light of the above detailed description. The terms used in the following claims should not be construed to limit the disclosure to the specific embodiments disclosed in the specification and the drawings. Rather, the scope of the disclosure is to be determined entirely by the following claims, which are to be construed in accordance with established doctrines of claim interpretation.

### Further Examples

Example 1 provides an exemplary method comprising: accessing a portable storage device to obtain an identifier and a set of test patterns to test a set of circuits of a computing system, the identifier to map to the set of test patterns; determining that the set of test patterns is to be executed on the computing system based on the identifier to be obtained from accessing the portable storage device; and responsive to the determination, executing the set of test patterns loaded from the portable storage device on the set of circuits of the computing system to detect one or more hardware defects of the set of circuits.
Example 2 includes the substance of Example 1, wherein determining that the set of test patterns is to be executed on the computing system comprises a determination that the identifier to be obtained from accessing the portable storage device matches to an identifier corresponding to the computing system.
Example 3 includes the substance of Examples 1 to 2, wherein the identifier corresponding to the computing system is a part identifier (PID), a die identifier, or silicon stepping ID.
Example 4 includes the substance of Examples 1 to 3, wherein the set of test patterns is to target structural defects of the set of circuits, including defects regarding layout of transistors within the computing system, and regarding connections between the transistors.
Example 5 includes the substance of Examples 1 to 4, wherein the detection of the one or more hardware defects is to be performed through a boot up process of the computing system.
Example 6 includes the substance of Examples 1 to 5, wherein the portable storage device is a Universal Serial Bus (USB) device, wherein the USB device is a USB Type-C device to operate at a power delivery (PD) alternate mode, and wherein the detection of the one or more hardware defects is to be initiated through a command.
Example 7 includes the substance of Examples 1 to 6, wherein the portable storage device is a Universal Serial Bus (USB) device, wherein the set of test patterns is identified with a USB class identifier, and wherein a USB driver or an operating system (OS) of the computing system is to coordinate operations of the detection of the one or more hardware defects based on the USB class identifier.
Example 8 includes the substance of Examples 1 to 7, wherein the set of test patterns is encrypted prior to being stored in the portable storage device, and the method further comprises: confirming integrity of the set of test patterns through authentication prior to executing the set of test patterns, wherein the set of test patterns is encrypted with an Advanced Encryption Standard (AES) encryption, and wherein integrity of the set of test patterns is confirmed decryption of the encrypted set of test patterns.
Example 9 includes the substance of Examples 1 to 8, wherein the set of test patterns is encrypted with an Advanced Encryption Standard (AES) encryption, and wherein the integrity of the set of test patterns is confirmed decryption of the encrypted set of test patterns.
Example 10 includes the substance of Examples 1 to 9, wherein the AES encryption to encrypt the set of test patterns is to operate at an AES counter mode, wherein a plurality of blocks is to be generated from the set of test patterns in the AES counter mode, and a block within the plurality of blocks is to include a counter, and wherein the counter identifies the computing system.
Example 11 includes the substance of Examples 1 to 10, wherein each of the plurality of blocks is encrypted through a first Secure Hash Algorithm (SHA) encryption to generate a first plurality of bytes.
Example 12 includes the substance of Examples 1 to 11, wherein the first plurality of bytes is encrypted through a second SHA encryption to generate a second plurality of bytes.
Example 13 includes the substance of Examples 1 to 12, wherein the second plurality of bytes is to be padded through a Public Key Cryptography Standards (PKCS) padding to generate a third plurality of bytes, wherein the third plurality of bytes is to be signed with an RSA (Rivest-Shamir-Adleman) private key to generate a signature.
Example 14 includes the substance of Examples 1 to 13, wherein the signature is saved as a header to be stored along with the third plurality of bytes.
Example 15 provides an exemplary apparatus comprising: a set of circuits within a computing system to be tested; and logic to detect one or more hardware defects of the set of circuits, the detection of the one or more hardware defects of the set of circuits is to: access a portable storage device to obtain an identifier and a set of test patterns to test the set of circuits, the identifier to map to the set of test patterns, determine that the set of test patterns is to be executed on the computing system based on the identifier to be obtained from accessing the portable storage device, and responsive to the determination, execute the set of test patterns loaded from the portable storage device on the set of circuits within the computing system to detect the one or more hardware defects.
Example 16 includes the substance of Example 15, wherein determining that the set of test patterns is to be executed on the computing system comprises a determination that the identifier to be obtained from accessing the portable storage device matches to an identifier corresponding to the computing system.
Example 17 includes the substance of Examples 15 or 16, wherein the identifier corresponding to the computing system is a part identifier (PID), a die identifier, or silicon stepping ID.
Example 18 includes the substance of Examples 15 to 17, wherein the set of test patterns is encrypted prior to being stored in the portable storage device, and integrity of the set of test patterns is confirmed through authentication by the logic prior to execution of the set of test patterns.
Example 19 provides an exemplary computer-readable storage medium storing instructions that when executed by a processor, are capable of causing the processor to perform: accessing a portable storage device to obtain an identifier and a set of test patterns to test a set of circuits of a computing system, the identifier to map to the set of test patterns; determining that the set of test patterns is to be executed on the computing system based on the identifier to be obtained from accessing the portable storage device; and responsive to the determination, executing the set of test patterns loaded from the portable storage device on the set of circuits of the computing system to detect one or more hardware defects of the set of circuits.
Example 20 includes the substance of Example 19, determining that the set of test patterns is to be executed on the computing system comprises a determination that the identifier to be obtained from accessing the portable storage device matches to an identifier corresponding to the computing system.

### Additional Explanation

Embodiments of the disclosure may include various steps, which have been described above. The steps may be embodied in machine-executable instructions which may be used to cause a general-purpose or special-purpose processor to perform the steps. Alternatively, these steps may be performed by specific hardware components that contain hardwired logic for performing the steps, or by any combination of programmed computer components and custom hardware components.

As described herein, instructions may refer to specific configurations of hardware such as application specific integrated circuits (ASICs) configured to perform certain operations or having a predetermined functionality or software instructions stored in memory embodied in a non-transitory computer-readable medium. Thus, the techniques shown in the Figures can be implemented using code and data stored and executed on one or more electronic devices (e.g., an end station, a network element, etc.). Such electronic devices store and communicate (internally and/or with other electronic devices over a network) code and data using computer machine-readable media, such as non-transitory computer machine-readable storage media (e.g., magnetic disks; optical disks; random access memory; read only memory; flash memory devices; phase-change memory) and transitory computer machine-readable communication media (e.g., electrical, optical, acoustical, or other form of propagated signals-such as carrier waves, infrared signals, digital signals, etc.). In addition, such electronic devices typically include a set of one or more processors coupled to one or more other components, such as one or more storage devices (non-transitory machine-readable storage media), user input/output devices (e.g., a keyboard, a touchscreen, and/or a display), and network connections. The coupling of the set of processors and other components is typically through one or more busses and bridges (also termed as bus controllers). The storage device and signals carrying the network traffic respectively represent one or more machine-readable storage media and machine-readable communication media. Thus, the storage device of a given electronic device typically stores code and/or data for execution on the set of one or more processors of that electronic device. Of course, one or more parts of an embodiment of the disclosure may be implemented using different combinations of software, firmware, and/or hardware. Throughout this detailed description, for the purposes of explanation, numerous specific details were set forth in order to provide a thorough understanding of the present disclosure. It will be apparent, however, to one skilled in the art that the disclosure may be practiced without some of these specific details. In certain instances, well-known structures and functions were not described in elaborate detail in order to avoid obscuring the subject matter of the present disclosure. Accordingly, the scope and spirit of the disclosure should be judged in terms of the claims which follow.

What is claimed is:

1. A method comprising:
accessing a portable storage device to obtain an identifier and a set of test patterns to test a set of circuits of a computing system, the identifier to map to the set of test patterns;
determining that the set of test patterns is to be executed on the computing system based on the identifier to be obtained from accessing the portable storage device; and
responsive to the determination, executing the set of test patterns loaded from the portable storage device on the set of circuits of the computing system to detect one or more hardware defects of the set of circuits.

2. The method of claim 1, wherein determining that the set of test patterns is to be executed on the computing system comprises a determination that the identifier to be obtained from accessing the portable storage device matches to an identifier corresponding to the computing system.

3. The method of claim 2, wherein the identifier corresponding to the computing system is a part identifier (PID), a die identifier, or silicon stepping ID.

4. The method of claim 1, wherein the set of test patterns is to target structural defects of the set of circuits, including defects regarding layout of transistors within the computing system, and regarding connections between the transistors.

5. The method of claim 1, wherein the detection of the one or more hardware defects is to be performed through a boot up process of the computing system.

6. The method of claim 1, wherein the portable storage device is a Universal Serial Bus (USB) device, wherein the USB device is a USB Type-C device to operate at a power delivery (PD) alternate mode, and wherein the detection of the one or more hardware defects is to be initiated through a command.

7. The method of claim 1, wherein the portable storage device is a Universal Serial Bus (USB) device, wherein the set of test patterns is identified with a USB class identifier, and wherein a USB driver or an operating system (OS) of the computing system is to coordinate operations of the detection of the one or more hardware defects based on the USB class identifier.

8. The method of claim 1, wherein the set of test patterns is encrypted prior to being stored in the portable storage device, and the method further comprises:
confirming integrity of the set of test patterns through authentication prior to executing the set of test patterns.

9. The method of claim 8, wherein the set of test patterns is encrypted with an Advanced Encryption Standard (AES) encryption, and wherein the integrity of the set of test patterns is confirmed decryption of the encrypted set of test patterns.

10. The method of claim 9, wherein the AES encryption to encrypt the set of test patterns is to operate at an AES counter mode, wherein a plurality of blocks is to be generated from the set of test patterns in the AES counter mode, and a block within the plurality of blocks is to include a counter, and wherein the counter identifies the computing system.

11. The method of claim 10, wherein each of the plurality of blocks is encrypted through a first Secure Hash Algorithm (SHA) encryption to generate a first plurality of bytes.

12. The method of claim 11, wherein the first plurality of bytes is encrypted through a second SHA encryption to generate a second plurality of bytes.

13. The method of claim 12, wherein the second plurality of bytes is to be padded through a Public Key Cryptography Standards (PKCS) padding to generate a third plurality of bytes, wherein the third plurality of bytes is to be signed with an RSA (Rivest-Shamir-Adleman) private key to generate a signature.

14. The method of claim 13, wherein the signature is saved as a header to be stored along with the third plurality of bytes.

15. An apparatus comprising:
a set of circuits within a computing system to be tested; and
logic to detect one or more hardware defects of the set of circuits, the detection of the one or more hardware defects of the set of circuits is to:
access a portable storage device to obtain an identifier and a set of test patterns to test the set of circuits, the identifier to map to the set of test patterns,
determine that the set of test patterns is to be executed on the computing system based on the identifier to be obtained from accessing the portable storage device, and
responsive to the determination, execute the set of test patterns loaded from the portable storage device on the set of circuits within the computing system to detect the one or more hardware defects.

16. The apparatus of claim 15, wherein determining that the set of test patterns is to be executed on the computing system comprises a determination that the identifier to be obtained from accessing the portable storage device matches to an identifier corresponding to the computing system.

17. The apparatus of claim 16, wherein the identifier corresponding to the computing system is a part identifier (PID), a die identifier, or silicon stepping ID.

18. The apparatus of claim 16, wherein the set of test patterns is encrypted prior to being stored in the portable storage device, and integrity of the set of test patterns is confirmed through authentication by the logic prior to execution of the set of test patterns.

19. A non-transitory computer-readable storage medium storing instructions that when executed by a processor, are capable of causing the processor to perform:
accessing a portable storage device to obtain an identifier and a set of test patterns to test a set of circuits of a computing system, the identifier to map to the set of test patterns;
determining that the set of test patterns is to be executed on the computing system based on the identifier to be obtained from accessing the portable storage device; and
responsive to the determination, executing the set of test patterns loaded from the portable storage device on the set of circuits of the computing system to detect one or more hardware defects of the set of circuits.

20. The non-transitory computer-readable storage medium of claim 19, wherein determining that the set of test patterns is to be executed on the computing system comprises a determination that the identifier to be obtained from accessing the portable storage device matches to an identifier corresponding to the computing system.
